(19) United States
(12) Patent Application Publication
(10) Pub. No.: US 2025/0142775 A1
(43) Pub. Date: May 1, 2025

(54) ELECTRONIC DEVICE COOLING SYSTEM AND RELATED SYSTEMS AND METHODS

(71) Applicant: GemaTEG Inc., Bellevue, WA (US)

(72) Inventors: Maurizio MIOZZA, Seattle, WA (US); Bruno LORENZI, Perugia (IT); Fabio FABBRIS, Gallarate (IT)

(73) Assignee: GemaTEG Inc., Bellevue, WA (US)

(21) Appl. No.: 18/927,376

(22) Filed: Oct. 25, 2024

Related U.S. Application Data
(60) Provisional application No. 63/593,289, filed on Oct. 26, 2023.

(51) Int. Cl. H05K 7/20; G06F 1/20

(52) U.S. Cl. CPC H05K 7/20281; G06F 1/20; H05K 7/20272; G06F 2200/201; H05K 7/20209

(57) ABSTRACT

Cooling systems for removing heat from an electronic device (e.g., a computing system), and related systems and methods, are disclosed herein. The cooling system can include multiple active cooling devices (e.g., thermoelectric devices) that are each independently thermally couplable to a processing unit in the electronic device. Further, each of the active cooling devices (and/or systems coupling the cooling device to the processing unit) can be independently operable to deliver localized cooling to the electronic device. The cooling system can also include one or more heat exchangers that are thermally coupled first hot side active cooling devices, as well as one or more external cooling loops that use fluid to cool the one or more heat exchangers.

### CROSS-REFERENCE TO RELATED APPLICATION(S)

This application claims priority to U.S. Provisional Application No. 63/593,289, filed Oct. 26, 2023, the entirety of which is incorporated herein by reference.

### TECHNICAL FIELD

The present technology is generally directed to thermal management of electronic devices and more specifically to the thermal management of electronic devices using thermoelectric devices and fluid cooling systems.

### BACKGROUND

The growth in complexity of microelectronics has introduced new challenges for thermal management. Multicore microprocessors provide unparalleled computing power for critical applications and high-performance computing at high thermal heat fluxes. Similar considerations apply to power electronics and any other advanced field involving electronic systems. The need for a more compact design adds a layer of complexity, with the envelope becoming tighter at higher power density. Looking forward, new families of microprocessors will push these limits even further.

The available solutions for thermal management of high-power electronics are either gas or liquid cooling systems. Gas cooling systems have limited heat transfer capacity with unfavorable form factors but are economical and easy to deploy. Liquid cooling, either in a single or two-phase arrangement, is a positive solution for high thermal dissipation power. Both technologies are mature with narrow margins of improvement. Extreme solutions, such as immersion cooling of the entire system in a dielectric fluid, address the current requirement but at high infrastructural and maintenance costs and significant safety issues.

### BRIEF DESCRIPTION OF THE DRAWINGS

FIG. 1 is a schematic block diagram of a system with a cooling system configured in accordance with embodiments of the present technology.

FIG. 2 is a partially schematic diagram of a pre-cooling chamber configured in accordance with embodiments of the present technology.

FIG. 3 is a schematic block of a system configured in accordance with embodiments of the present technology.

FIG. 4 is a partially schematic cross-sectional view of a heat exchanger configured in accordance with embodiments of the present technology.

FIG. 5 is a partially schematic isometric view of a heat exchanger configured in accordance with embodiments of the present technology.

FIG. 6 is a partially schematic cross-sectional view of a fluid cooling system configured in accordance with embodiments of the present technology.

FIG. 7 is a block diagram of a system with a localizable cooling subsystem configured in accordance with embodiments of the present technology.

FIG. 8 is a block diagram of a system with a localizable cooling subsystem configured in accordance with further embodiments of the present technology.

FIG. 9 is a flow diagram of a process for operating a cooling subsystem in accordance with further embodiments of the present technology.

FIG. 10 is a flow diagram of a process for operating a cooling subsystem in accordance with further embodiments of the present technology.

FIG. 11 is a flow diagram of a process for operating a cooling subsystem in accordance with further embodiments of the present technology.

FIG. 12 is a block diagram illustrating an overview of devices on which some embodiments of the present technology can operate.

FIG. 13 is a block diagram illustrating components of a computing device configured in accordance with some embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

### Overview

Cooling systems for removing heat from an electronic device (e.g., a computing system, a supercomputing device, and/or the like), and related systems and methods, are disclosed herein. The cooling system can include multiple active cooling devices (e.g., thermoelectric devices) that are each independently thermally couplable to one or more processing units in the electronic device. Further, each of the active cooling devices, as well as any systems coupling the cooling device to the processing unit(s), can be independently operable. For example, a first cooling device (e.g., a first thermoelectric device) can be operated independently from a second cooling device to deliver different levels of cooling to different processing units in the electronic device. Said another way, the cooling system can deliver locally customizable cooling (e.g., localized cooling) to the electronic device. As discussed in more detail below, the cooling system can also include various fluid loops to help thermally couple the cooling devices to corresponding processing units and/or to help remove heat from a hot side of the cooling devices.

Additionally, or alternatively, the cooling system can further include a controller that independently controls operating parameters for each component of the cooling system. Purely by way of example, the controller can (1) deliver a first electrical current to a first thermoelectric component (sometimes also referred to herein as a “thermoelectric device”) to create a first temperature gradient, and therefore provide a first level of cooling from the first thermoelectric component to a first processing unit; (2) deliver a second electrical current to a second thermoelectric component to create a second temperature gradient, and therefore provide a second level of cooling from the second thermoelectric component to a second processing unit; (3) adjust a first flow rate of fluid in a loop between the first thermoelectric component and the first processing unit; (4) adjust a second flow rate of fluid in a loop between the second thermoelectric component and the second processing unit; and/or (5) adjust a third flow rate of fluid in an external loop to carry heat away from the first and/or second thermoelectric components. As further discussed in more detail below, the adjustments can be based on a temperature at the processing units, workloads at the processing units, thermal loads at the processing units, temperature thresholds that are specific to the processing units and/or computing operations at the processing units, energy consumption requirements, and/or the like.

For case of reference, the cooling system and components thereof are sometimes described herein with reference to top and bottom, upper and lower, upwards and downwards, device-facing and external-facing, hot-side and cold-side, and/or horizontal plane, x-y plane, vertical, or z-direction relative to the spatial orientation of the embodiments shown in the figures. It is to be understood, however, that the cooling system and components thereof can be moved to, and used in, different spatial orientations without changing the structure and/or function of the disclosed embodiments of the present technology.

Further, although primarily discussed herein in the context of cooling the components of a supercomputer and/or server device, one of skill in the art will understand that the scope of the invention is not so limited. For example, the cooling system can also be implemented in various other electronic devices and/or other systems requiring localized cooling. Accordingly, the scope of the invention is not confined to any subset of embodiments, and is confined only by the limitations set out in the appended claims.

High-Performance Computing (HPC) systems, which often include multiple supercomputers, house numerous high-performance processors. The processors can work in parallel to tackle computationally intensive tasks. The computationally intensive tasks, in turn, can generate a substantial amount of heat. The heat, if unaddressed, can undermine the processing power of the HPC system (e.g., by requiring increased refresh rates that slow computing down), can degrade the quality of the processors, and/or shorten an overall lifespan of the processors. As a result, meeting demands for increased computational power and speed will require solutions for cooling the HPC systems (and the processors therein). One potential solution is to use liquid cooling systems, which offer superior heat dissipation compared to traditional air-cooling approaches. For example, liquids can have a relatively high heat conductivity, thereby facilitating effective heat transfer from the processors to a cooling fluid. The fluid can then be cycled and cooled to continue to draw heat away from the processors at a relatively high rate. As a result, the fluid cooling systems can help prevent thermal throttling and help ensure optimal performance from the processors in the HPC systems.

Further, in parallel computation, processors (or microprocessors) may require varying levels of cooling power based on their workload and/or thermal characteristics specific to each of the processors. Purely by way of example, a system with four microprocessors operating in parallel may have only a single microprocessor above a temperature threshold and needing to be cooled. In this example, it can be inefficient to operate a cooling system that is shared by each of the microprocessors. Additionally, or alternatively, the shared cooling system can result in temperature variations among the microprocessors, leading to performance discrepancies and/or thermal-related issues. For example, the shared cooling systems can include large heat exchangers and/or large cooling reservoirs that are slow to respond to changes in thermal loads at a single microprocessor. The slow response of a typical heat exchanger cannot control the temperatures as required by a grouping of microprocessors, which require a more timely (e.g., rapid) response. As a result, the lone microprocessor overheating may not receive enough cooling from the shared system, resulting in thermal throttling (e.g., the microprocessor slows down and becomes a bottleneck for an entire multi-node or multi-processor system). The throttling can also undermine communication between the microprocessors, further reducing the computing power of the whole system.

Furthermore, the microprocessors can each respond differently to thermal loads (e.g., have different thermal properties), thereby requiring a different response from the cooling systems. Said another way, a cooling operation sufficient to keep a first microprocessor from throttling may be insufficient to keep a second microprocessor from throttling. As a result, the cooling system must operate in accordance with the most sensitive microprocessor to avoid throttling in the computing system. As a result, the cooling system can require large amounts of energy to maintain the operation of the computing system, offsetting some of the benefits of including the cooling system in the computing system (e.g., making it significantly more expensive to operate the computing system). Systems and methods that help address the shortcomings discussed above are disclosed herein.

### DESCRIPTION OF THE FIGURES

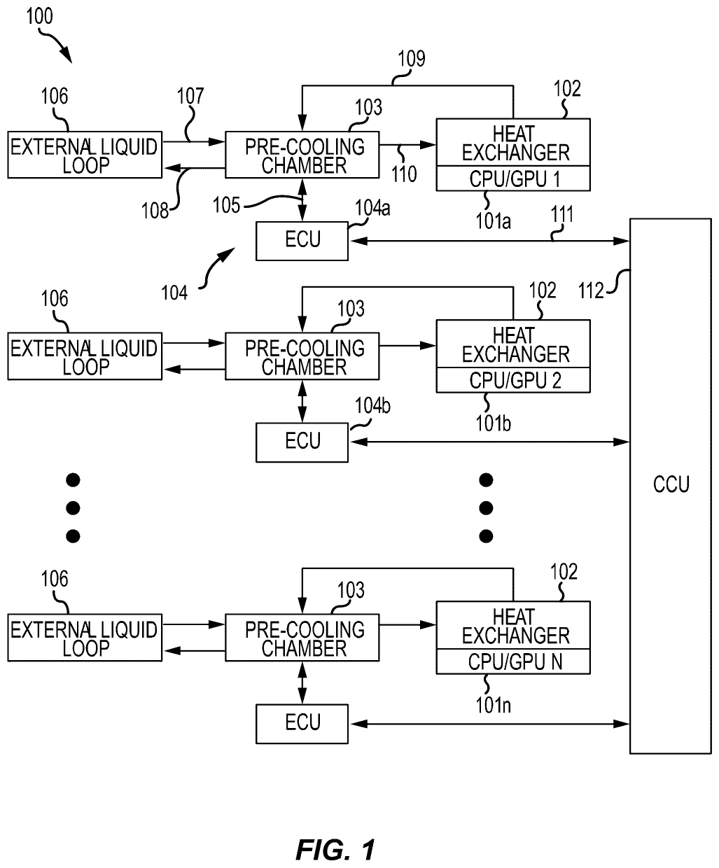

FIG. 1 is a schematic block diagram of a system with a liquid cooling system 100 configured in accordance with embodiments of the present technology. More specifically, FIG. 1 schematically illustrates an example of an electronic device system that includes a liquid cooling system 100 (“cooling system 100”) that can provide processor-specific cooling. In some embodiments, the electronic device system can encompass configurations such as multi-node systems, server racks, and/or similar systems that include multiple processors. For example, the electronic device system can include n-different electronic components, including a first electronic component 101a, a second electronic component 101b, and so on to an nth electronic component 101n. Each of the electronic components 101 can include a central processing unit (CPU), a graphic processing unit (GPU), and/or any other suitable processing unit. In some embodiments, the electronic device system can include accelerators or superchips. The superchip can include a combination of a CPU and GPU and also fast memories to more easily containerize neural net models on local workstations to stage them for cloud computing and artificial intelligence applications.

As discussed above, the first-nth electronic components 101a-101n can be run in parallel or in series. As a result, each of the first-nth electronic components 101a-101n can be subjected to a different workload. As used herein, the workload (sometimes referred to as “load” for short) is a measure of the amount of computational work that an electronic component performs. In turn, the workload at an electronic component result in a thermal load at the electronic component. Because each of the first-nth electronic components 101a-101n can be subjected to a different workload, each of the first-nth electronic components 101a-101n (and the CPUs/GPUs therein) can be subjected to a different thermal load.

To help address the variations in workload (and the resulting variations in thermal load), the cooling system 100 illustrated in FIG. 1 is configured to provide individualized cooling to each of the first-nth electronic components 101a-101n. For example, the cooling system 100 can include heat exchangers 102, pre-cooling chamber(s) 103, and external liquid loop(s) 106 that are individually thermally coupled to each of the first-nth electronic components 101a-101n. More specifically, the heat exchangers 102 can each be in thermal contact with one of the first-nth electronic components 101a-101n. The heat exchangers 102, in turn, are coupled to the pre-cooling chamber(s) 103 via a first input line 110 and a first output line 109. The heat exchangers 102, first input line 110 (sometimes also referred to as an “internal input channel” and/or the like), and the first output line 109 (sometimes also referred to as an “internal output channel” and/or the like) are sometimes referred to collectively as an internal cooling loop. Similarly, the pre-cooling chamber(s) 103 are coupled to the external liquid loop(s) 106 via a second input line 107 and a second output line 108. The external liquid loop(s) 106, the second input line 107 (sometimes also referred to as an “external input channel” and/or the like), and a second output line 108 (sometimes also referred to as an “external output channel” and/or the like) are sometimes referred to collectively as an external cooling loop.

In the illustrated embodiment, the cooling system 100 includes an individual one of the pre-cooling chambers 103 for each of the first-nth electronic components 101a-101n. However, it will be understood that the technology is not so limited. For example, the cooling system 100 can include a single pre-cooling chamber 103 that is individually coupled to each of the heat exchangers 102 via corresponding input and output lines 110, 109. In another example, the cooling system 100 can include multiple pre-cooling chambers 103 that are each coupled to two or more of the heat exchangers 102 via corresponding input and output lines 110, 109. Similarly, in the illustrated embodiment, the cooling system 100 includes an individual one of the external liquid loops 106 for each of the first-nth electronic components 101a-101n. However, in various other embodiments, the external liquid loops 106 can be thermally coupled to any subset (or all) of the first-nth electronic components 101a-101n.

As illustrated in FIG. 1, the pre-cooling chamber(s) 103 can act as an intermediate between the external liquid loop(s) 106 and the heat exchangers 102. For example, as discussed in more detail below, the pre-cooling chambers 103 can each include a first heat exchanger that interacts with fluids on the electric device side (e.g., along the first input line 110 and the first output line 109), a second heat exchanger that interacts with fluids on the external loop side (e.g., along the second input line 107 and the second output line 108), and a heat transfer device coupled between the first and second heat exchangers. In some embodiments, the heat transfer device is an active heat transfer device, such as a thermoelectric device, that provides active cooling to the first heat exchanger while dumping excess heat into the second heat exchanger.

As a result, to cool the first electronic component 101a, the pre-cooling chamber 103 can set the temperature of a fluid before the fluid enters one or more of the heat exchangers 102 along the first input line 110. The temperature of the fluid in the first input line 110 can be below a temperature within the first electronic component 101a. As a result, as the fluid moves through the heat exchanger 102, the fluid can absorb heat from the heat exchanger 102 (and/or the first electronic component 101a) and return to the pre-cooling chamber 103 along the first output line 109. That is, the fluid can cool (e.g., remove heat from) the heat exchanger 102, thereby allowing the heat exchanger 102 to cool the first electronic device 102a. Further, because the heat exchanger 102 and the fluid can each have a higher coefficient of heat transfer than air, the cooling system 100 can remove more heat from the first electronic component 101a than a traditional air cooling system.

The fluid returning along the first output line 109, in turn, needs to be cooled to reset the temperature of the fluid. The pre-cooling chamber 103, configured in accordance with the embodiments discussed above, can absorb heat from the returning fluid and transfer the heat to a second fluid that is cycled between the external liquid loop 106 and the pre-cooling chamber 103 via the second input line 107 and the second output line 108. By providing an active driver within the pre-cooling chamber 103 (e.g., a thermoelectric device), the cooling system 100 can improve a speed at which the fluid is reset and/or increase the amount of heat the pre-cooling chamber 103 is able to remove from the fluid before it is recycled back to the heat exchanger 102. Similar to the fluid on the electronic device side, the fluid in the external liquid loop 106 can have a temperature set by an external component (e.g., an external cooling device, an external heat sink, and/or the like), flow through the pre-cooling chamber to cool the peripheral side, then return to the external component to dump the absorbed heat.

As further illustrated in FIG. 1, the cooling system 100 can also include one or more electronic control units (ECUs) 104 (n-number illustrated in FIG. 1) and a central control unit (CCU) 112 communicably coupled to each of the ECUs 104 via a communication channel 111 (e.g., a wired and/or wireless communication channel). The ECUs 104 can each be operatively coupled to a corresponding one of the pre-cooling chambers 103 via a path 105 (e.g., via direct coupling, via a communicative coupling to one or more sensors in the pre-cooling chambers 103, and/or the like). Further, each of the ECUs 104 can operate in a closed-loop mode to read the temperature and/or flow rates of the fluid from the external liquid loop 106 and/or the fluid from the heat exchangers 102 via dedicated thermal sensors. For example, a first ECU 104a can read the temperature of fluids from the first electronic component 101a while a second ECU 104b can read the temperature from the second electronic component 101b.

The ECUs 104 can then communicate the temperatures and/or flow rates (sometimes referred to collectively as “conditions”) to the CCU 112. The CCU 112 can include various communication interfaces and a memory. The communication interfaces can be communicably coupled to the CCU 112 to each of the ECUs 104 and/or various peripheral devices (e.g., a remote computing system). The memory can store instructions for controlling the operation of the cooling system 100. Additionally, or alternatively, the memory CCU 112 can build a thermal map of the first-nth electronic components 101a-101n, store the map within the memory, update the map with up-to-date conditions via communications from the ECUs 104, and identify processors and/or CPU/GPUs that are entering thermal throttling.

During the operation of the cooling system 100, the CCU 112 can receive communications from the ECUs and control various operations of the cooling system 100 in response. For example, the CCU 112 can receive a first thermal signal from the first ECU 104a, as well as a second thermal signal from the second ECU 104b. The first thermal signal (e.g., a measurement of the temperature of the fluid in the device-side loop) can be indicative of a first thermal load at the first electronic component 101a. Similarly, the second thermal signal can be indicative of a second thermal load at the second electronic component 101b. The CCU 112 can then maintain, adjust, regulate, modify, and/or otherwise control operation of the cooling system 100 based on the first and second thermal signals. For example,

For example, the CCU 112 can analyze the thermal profile of the first and second electronic components 101a, 101b (and/or any other electronic components), then determine one or more adjustments to the operation of the cooling system 100 based on the thermal profiles to increase the cooling power of the pre-cooling chambers 103 any electronic components experiencing thermal throttling or overheating. The adjustments can include, for example, changes in the flow rate of the fluid in the device-side loop (e.g., between the pre-cooling chambers 103 and the heat exchangers 102), changes in the flow rate of the fluid in the external-side loop (e.g., between the pre-cooling chambers 103 and the external liquid loop 106), and/or changes to the operation of the pre-cooling chambers 103 (e.g., increasing a drive current delivered to a thermoelectric device to increase the cooling delivered). Further, the CCU 112 can analyze the response of each of the pre-cooling chambers 103 (e.g., changes in the thermal profiles) to the changes and make additional changes based on the response. Additionally, or alternatively, the CCU 112 can continue to monitor the thermal profile at each of the pre-cooling chambers 103 and make additional adjustments over time. That is, the adjustments are transient and specific to current conditions. As thermal loads (and/or any associated thermal throttling) shift with workload variation, the cooling system 100 will require further adjustments (e.g., to increase and/or decrease cooling power). Because the cooling system 100 can target specific electronic components, the cooling system 100 can be more responsive to hot spots and thermal throttling. Further, because each device-side loop is smaller than a system-wide cooling loop, the cooling system can have a shorter response time than a system with a larger footprint (e.g., because smaller volumes of liquid need to be cooled). In various embodiments, the response time of the cooling system 100 can be on the order of seconds, less than seconds, and/or hundreds of milliseconds.

In some embodiments, the CCU 112 can be communicatively coupled to the first-nth electronic devices 101a-101n and/or another device that distributes work amongst the first-nth electronic devices 101a-101n. In such embodiments, the CCU 112 can directly track a workload applied to each of the first-nth electronic devices 101a-101n, as well as a thermal response from the first-nth electronic devices 101a-101n to the workload. Over time, the CCU 112 can develop a map (e.g., a look-up-table and/or the like) and/or a predictive model that allows the CCU 112 to predict how the first-nth electronic devices 101a-101n will respond to their current workload. In such embodiments, the CCU 112 can make pre-emptive adjustments to the cooling system 100 based on a predicted thermal profile at the first-nth electronic devices 101a-101n in response to their workloads (e.g., to preemptively cool the first electronic component 101a when the workload at the first electronic component 101a goes up). That is, the CCU 112 can predict, pre-emptively address, evaluate, and correct the thermal throttling of the respective first-nth electronic devices 101a-101n by increasing (or decreasing) the cooling power delivered to each of the first-nth electronic devices 101a-101n.

Said another way, the memory in the CCU 112 can store the thermal mapping of a grouping of multiple processors of the electronic components 101 over a period of time. Processing of the thermal mapping data can result in predictable patterns, with certain processors more exposed and/or symptomatic to overheating and thermal throttling. The CCU 112 can then increase the cooling power to the electronic components 101 prone to overheating before the workload is increased. Said yet another way, the CCU 112 for the electronic device system can be configured to recognize a cooling pattern of the liquid cooling system and increase cooling to electronic components prone to overheating prior to establishing a thermal load. For the pre-cooling chamber 103 with thermoelectric modules, the extra cooling power allows the corresponding electronic component to withstand higher workloads (and therefore higher thermal loads) without overheating. Additionally, or alternatively, the control system including the CCU 112 can be configured to establish a thermal profile of the liquid cooling system 100 (e.g., how components of the cooling system respond to varying inputs, such as changes in flow rate and/or different drive rates of the active cooling components). The CCU 112 can store sufficient data sets at a system level to apply deep learning methodology, recognizing specific patterns or thermal maps of a grouping of multiple processors and optimizing cooling patterns.

In some embodiments, the CCU 112 control system balances (or minimizes) power consumption from the cooling system 100 while providing cooling to the first-nth electronic devices 101a-101n. For example, as discussed above, the pre-cooling chamber 103 can be energized (e.g., by the ECUs 104) to drive active cooling. But processors with lighter workloads require less active cooling to avoid (or correct) thermal throttling. Accordingly, the CCU 112 can vary the energy delivered to each of the pre-cooling chambers 103 to vary the amount of cooling delivered to each of the first-nth electronic devices 101a-101n. The variation can be based on predetermined temperature thresholds, predetermined thermal throttling thresholds, user-selected thresholds, performance requirements, energy consumption requirements, power-to-cool vs. power-to-operate ratios (e.g., how much power it will take to complete a computing operation at a throttled level compared to the power to cool the computing device), and/or the like. In a specific, non-limiting example, the CCU 112 can select an ideal cooling power based on thermal load and overall power consumption for the cooling system 100 and/or for groups of the first-nth electronic devices 101a-101n that are electronically coupled to be run in parallel or in series. In some embodiments, the ideal cooling power is based on an importance of a computing operation and/or an importance of the timing of a computing operation. For example, a computing operation requiring real-time processing can justify higher power consumption to cool the first-nth electronic devices 101a-101n while a computing operation with no deadline can justify reducing the power consumption of the cooling system 100. In some embodiments, the ideal cooling power is specific to each of the first-nth electronic devices 101a-101n.

In some embodiments, control of the cooling system 100 is split between the CCU 112 and the ECUs 104. For example, the CCU 112 can define predetermined temperature thresholds and associated tweaks to the operating conditions of the cooling system 100 at the temperature thresholds. The ECUs 104 can then control the cooling system 100 while the CCU 112 supervises and makes adjustments to the temperature thresholds, the operating conditions at the thresholds, and/or current operating conditions based on analyses of the performance of the cooling system 100. In some such embodiments, the ECUs 104 can include an embedded algorithm regulating the liquid temperature in the pre-cooling chamber 103 that is set by the CCU 112. Said another way, the localized cooling of the first-nth electronic devices 101a-101n can occur at two levels: a first level that is specific to each of the electronic components with the corresponding one of the ECUs 104, and a system-wide level via the CCU 112.

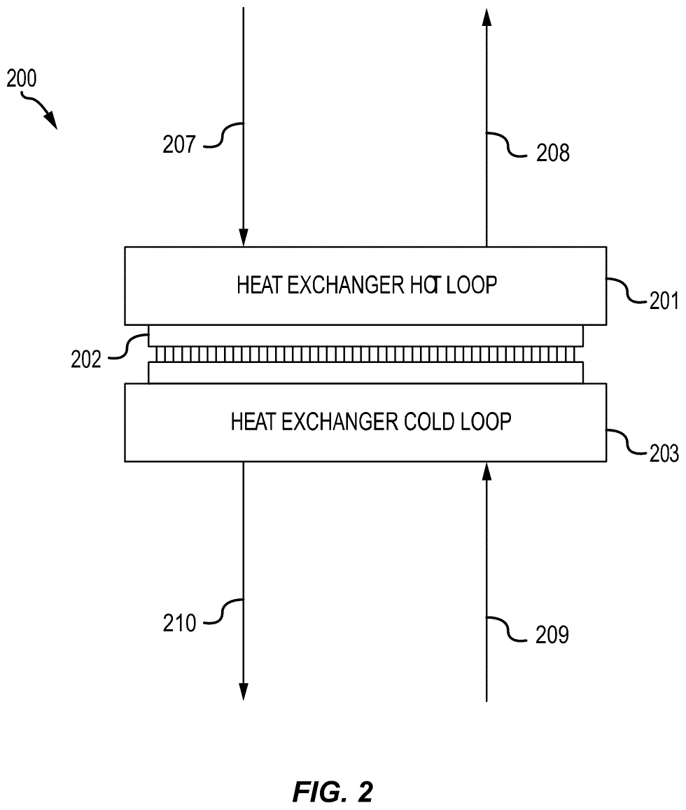

FIG. 2 is a partially schematic diagram of a pre-cooling chamber 200 configured in accordance with embodiments of the present technology. The pre-cooling chamber 200 illustrated in FIG. 2 is generally similar (or identical) to the pre-cooling chamber 103 discussed above with reference to FIG. 1. For example, as illustrated in FIG. 2, the pre-cooling chamber 200 can include a first heat exchanger 201, a second heat exchanger 203, and a thermoelectric device 202 thermally coupled between the first and second heat exchangers 201, 203. Further, the first heat exchanger 201 is coupled to a first input channel 207 and a first output channel 208, and the second heat exchanger 203 is coupled to a second input channel 209 and a second output channel 210. Still further, the first input channel 207 and the first output channel 208 can interface with a peripheral liquid loop (e.g., the external liquid loop 106 of FIG. 1), and the second input channel 209 and the second output channel 210 can interface with a device-facing loop (e.g., facing the heat exchanger 102 of FIG. 1).

During operation, the thermoelectric device 202 can actively cool the second heat exchanger 203. More specifically, a current applied to the thermoelectric device 202 can cause the thermoelectric device 202 to move heat from the second heat exchanger 203 (sometimes also referred to as a “cold-side heat exchanger,” a “cold loop heat exchanger,” and/or the like) to the first heat exchanger 201 (sometimes also referred to as a “hot-side heat exchanger,” a “hot loop heat exchanger,” and/or the like). Said another way, the thermoelectric device 202 can establish a thermal gradient between the first heat exchanger 201 and the second heat exchanger 203 that, in turn, causes heat to flow from the second heat exchanger 203 to the first heat exchanger 201.

As a result, as the second heat exchanger 203 receives fluids from a device-facing loop (e.g., from the heat exchanger 102 of FIG. 1) via the second input channel 209, the second heat exchanger 203 can absorb heat from the fluid. The second heat exchanger 203 can then transfer the heat toward the first heat exchanger 201 and direct a cooled fluid back into the device-facing loop via the second output channel 210. In turn, the first heat exchanger 201 can receive the heat from the second heat exchanger 203 and transfer the heat into a fluid that then flows out of the first heat exchanger 201 via the first output channel 208 into an external liquid loop. The fluid can then travel to a thermal sink (e.g., a larger heat exchanger, heat dissipator, and/or active cooling device) to expel the heat before returning to the first heat exchanger 201 via the first input channel 207.

Said another way, a thermal load at an associated electronic device can be at least partially transferred into a fluid that flows into the pre-cooling chamber 200 along the second input channel 209. The thermal load can then be absorbed by the second heat exchanger 203, transferred to the first heat exchanger 201, and dissipated via a peripheral cooling loop. As a result, the pre-cooling chamber 200 can return a cooled fluid to the associated electronic device.

Thermoelectric devices can provide advantages for electronics thermal management, including reliability, fast response time, dual-purpose (e.g., cooling and power harvesting), and no moving parts. Thermoelectric modules generally refer to active devices that, once energized with electric power, act as a heat pump or, in the presence of a thermal gradient, harvest a portion of the heat flux and convert it into electrical energy. Examples described herein include systems incorporating an integrated approach to thermoelectric architecture to address the high thermal flux of electronic device systems and electronic components in a compact design. The coolant can include a single-phase liquid, in some embodiments.

In some embodiments, the thermoelectric device 202 (sometimes also referred to herein as a “thermoelectric system”) can integrate an array of thermoelectric elements. The array of thermoelectric elements can help increase (or maximize) the efficiency of the pre-cooling chamber 200 (and/or the cooling system more generally), especially at high heat loads, compared to a singular thermoelectric module. Additionally, or alternatively, the array of thermoelectric elements can respond to heat loads more quickly than a singular thermoelectric module, allowing the pre-cooling chamber 200 to quickly respond to a thermal load. In some embodiments, the thermoelectric device 202 responds to a thermal load on a CPU/GPU in thermal communication with the thermoelectric device 202 in less than 20 seconds (e.g., halting an increase in temperature at the CPU/GPU in less than 20 seconds, and/or the like). In some embodiments, the thermoelectric device 202 reduces the thermal load on the CPU/GPU (e.g., cooling the CPU/GPU a predetermined amount, cooling the CPU/GPU to a predetermined threshold, cooling the CPU/GPU to a steady state and/or the like) in less than 15 minutes, in less than 10 minutes, or in less than 5 minutes. In some embodiments, the thermoelectric device 202, once activated to adjust temperatures, establishes the intended cooling power in less than one second. In other words, the pre-cooling chamber 200 can instantaneously manage the thermal load from the CPU/GPU. As the temperature of the CPU/GPU begins to decrease immediately, the temperature of the thermoelectric device 202 can adjust and begin to establish and/or restore a steady state. In some embodiments, the thermoelectric device 202 can restore steady state operation and stabilization in less than 15 minutes, in less than 10 minutes, or in less than 5 minutes, depending on the inherent characteristics of the electronic device system. In some embodiments, the thermoelectric device 202 can restore steady state operation and stabilization in less than 1 minute, in less than 30 seconds, less than 10 seconds, or less than 1 second.

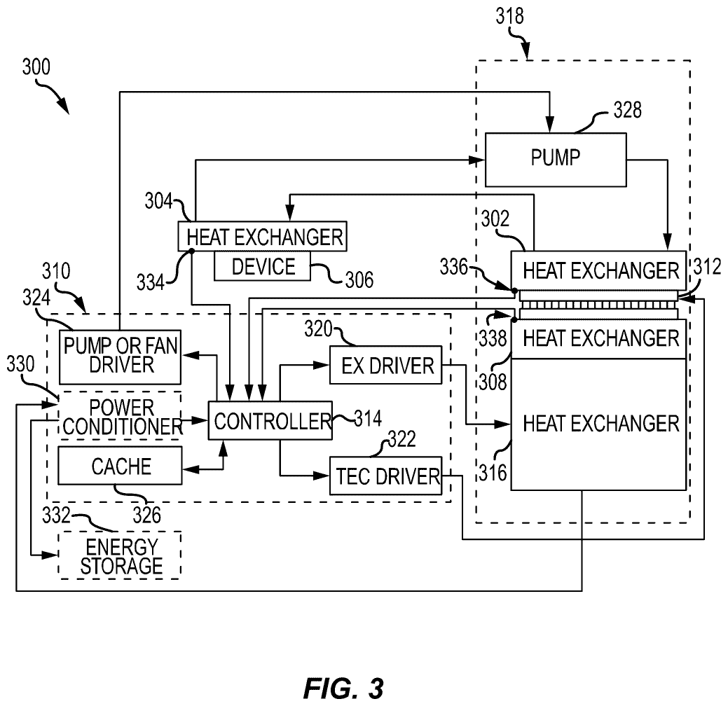

FIG. 3 is a schematic block of a system 300 configured in accordance with embodiments of the present technology. The system 300 is arranged to regulate a temperature of an electronic device system 306. The system 300 can include a heat exchanger 304, a first temperature sensor 334, a control system 310, and a fluid cooling system 318. The fluid cooling system 318 can be generally similar to the pre-cooling chambers discussed above. In the illustrated embodiments, the fluid cooling system 318 includes a pump 328, a first heat exchanger 302, a thermoelectric device 312, a second heat exchanger 308, a third heat exchanger 316, a second temperature sensor 336, and a third temperature sensor 338. In various embodiments, the third heat exchanger 316 can be generally similar (or identical) to and/or can interface with the external liquid loop 106 of FIG. 1. In the illustrated embodiments, the control system 310 includes a controller 314, a driver 324, a driver 320, a driver 322, and cache 326 (e.g., a memory device). In some embodiments, the control system 310 includes power conditioner 330. The power conditioner 330 can be coupled to energy storage 332 and/or an energy source.

Prior to operation (or during calibration operations), the fluid cooling system 318 and/or the control system 310 can determine, identify, and/or establish the operating parameters with the thermoelectric device 312 and the pump 328 to achieve a predetermined performance with a particular workload at specific boundary conditions for each of the heat exchanger 304, the first heat exchanger 302, and/or the second heat exchanger 308. The operating parameters can include electrical currents delivered to the thermoelectric device 312 to generate and/or maintain a temperature gradient between the first and second heat exchangers 302, 308; temperature gradients for the thermoelectric device 312; flow rates, pressures, and/or drive rates for the pump to control a flow of fluid between the heat exchanger 304 and the first heat exchanger 302; and/or the like. In some embodiments, the fluid cooling system 318 and/or the control system 310 sets operating parameters based on the actual thermal load, the boundary conditions, and the electronic device system characteristics.

The control system 310 can identify and/or store the operating parameters for use at various conditions (e.g., varying workloads at the electronic device system 306, various detected temperatures, various changes in temperatures, various boundary conditions within the heat exchangers, and/or the like). For example, the various conditions and the identified operating parameters can be stored in a look-up table within the cache 326 (or other suitable memory device). The storage can allow the control system 310, and the fluid cooling system 318, to quickly respond to changes in the conditions, reduce (or avoid) transient temperature spikes in the electronic device system, and/or predictively adjust operating parameters based on a workload assigned to the electronic device system 306.

In some embodiments, the control system 310 is a closed-loop system. For example, the control system 310 can implement an adaptive control methodology to continuously adjust the electrical current to the thermoelectric device 312 and/or the operating speeds of the pump 328. The adjustments can be based on adjustments to the workload at the electronic device system 306, varying specifications of user preferences (e.g., energy-saving modes vs. maximized cooling modes), time-dependence of the workload at the electronic device system 306 (e.g., real-time computing operation vs. long-running computing operations), varying importance of the computing operations, and/or the like. Additionally, or alternatively, the adjustments can be based on a measured efficacy of different operating parameters (e.g., measured based on cooling provided over time, cooling provided versus power consumed for cooling, and/or the like)

The fluid can flow from an output of the heat exchanger 304 to an input of the first heat exchanger 302 in the fluid cooling system 318. Similar to the discussion above, the first heat exchanger 302 can cool the fluid. The cooled fluid can then return from an output of the first heat exchanger 302 to an input of the heat exchanger 304 (e.g., creating a closed-system loop). In this manner, the fluid is cooled using the fluid cooling system 318 and provided to the heat exchanger 304 to extract heat from the electronic device system 306. In the fluid cooling system 318, the thermoelectric device 312 and heat exchanger 308 may be used to further regulate the cooling of the fluid. In some embodiments, the heat exchanger 316 may also exhaust waste heat into an environment and/or capture heat for the generation of energy.

As discussed above, the control system 310 can control various components of the system 300 based on temperatures within the system 300. For example, the first temperature sensor 334 can be positioned to measure a temperature of a portion of the heat exchanger 304 and/or electronic device system 306. The first temperature sensor 334 can then communicate the temperature to the controller 314. Similarly, the second temperature sensor 336 can be positioned to measure a temperature of a portion of the heat exchanger 302 and communicate the temperature to controller 314. Further, the third temperature sensor 338 can be positioned to measure a temperature of a portion of the heat exchanger 308 and communicate the temperature to controller 314.

In another example, the controller 314 can be operably coupled to drivers 320, 322, 324, and the cache 326. The driver 320 is operably coupled to the heat exchanger 316 to control operation of the heat exchanger 316 (e.g., to drive an external fluid loop). The driver 322 is operably coupled to thermoelectric device 312 to control the operation of the thermoelectric device 312 (e.g., to deliver an electrical current to the thermoelectric device 312). The driver 324 is operably coupled to the pump 328 to control the operation of the pump 328 (e.g., to control a speed of the pump 328). The cache 326 is operably coupled to the controller 314 and can store one or more values or programs used by the power conditioner 330. The power conditioner 330 can be operably coupled to the controller 314 and the heat exchanger 316 to condition power generated by the heat exchanger 316. The power conditioner 330 is operably coupled to energy storage 332 and may store some or all of the power or other energy generated by the heat exchanger 316 in the energy storage 332.

Examples of systems described herein accordingly may transfer heat from electronic components 101 and/or electronic device systems, such as electronic component 101a of FIG. 1. Examples of electronic device systems include one or more central processing units (CPUs), graphics processing units (GPUs), processors, servers, circuitry (e.g., one or more transistors, resistors, inductors), solid state drives, batteries, and/or memory devices. The electronic component 101 may be included in an assembly (e.g., case, package, system, and device). The temperature of the assembly may be used to provide fluid control in some embodiments. In some embodiments, electronic device systems cooled herein may have a small form factor (e.g., below 50 square centimeters) and high heat flow (e.g., less than about 10 Watts per square centimeter). Examples of electronic device systems described herein may find use in a wide array of systems. The components of FIG. 3 are exemplary. It will be understood that additional, fewer, and/or different components can be included in other embodiments of the present technology. Purely by way of example, the system 300 can include a recovery system that harvests a portion of the waste heat. The harvested waste heat can be converted into electrical energy and/or used for various other productive purposes (e.g., directed to various heating appliances).

The heat exchanger 304 may extract heat from the electronic device system 306 primarily using conduction and/or convection in some embodiments. The heat exchanger 304 may be in thermal contact with the electronic device system 306. In various embodiments, the heat exchanger 304 can be in direct contact, attached to, and/or integrated with the electronic device system 306. For example, a surface of the heat exchanger 304 may be positioned such that heat from the electronic device system 306 (e.g., from circuitry and/or any portion of an assembly enclosing circuitry) may be transferred to the heat exchanger 304. The heat exchanger 304 may have a cavity through which a fluid may flow. The heat exchanger 304 may have an inlet for providing fluid into the cavity, and an outlet for fluid exiting the cavity (and/or exiting the heat exchanger 304). A flow rate of the fluid through the heat exchanger 304 may be set and controlled by a control system described herein. Heat may be transferred by convection from the electronic device system 306 to a fluid partially or wholly filling a cavity of the heat exchanger 304.

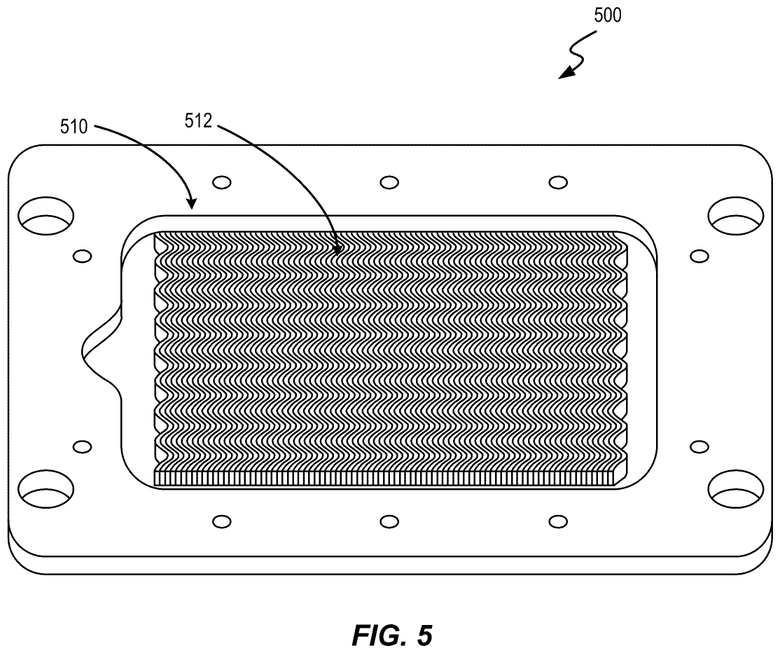

Heat exchangers described herein, such as heat exchanger 304, may accordingly define a cavity through which fluid may flow. Heat exchangers, such as heat exchanger 304, may include one or more structures positioned wholly or partially in the cavity which may alter the flow of the fluid. In a specific, non-limiting example, the fluid can flow through the heat exchanger 304 and interact with structures and/or surfaces to absorb heat from the heat exchanger 304. In some embodiments, fluid flow is altered by the structures to create one or more eddies in a flow of the fluid. An example structure is shown and described below in FIG. 5. However, other examples of structures can include microchannels, walls, pins, pillars, protrusions, depressions, or other alterations in a cavity that may affect the flow of a fluid through the cavity. The structures can promote heat transfer between the fluid and the structures. For example, one or more metals can be used to form the cavity and/or structures. Examples include aluminum, copper, or nickel. Further, the heat exchanger 304 can include one or more structures to reduce and/or minimize the form factor and increase a transfer of cooling. In some embodiments, the geometry and/or structures located in a cavity of the heat exchanger 304 are selected to increase the heat transfer coefficient at low flow rates, which may increase heat transfer to the fluid at low operating speeds of the pump 328.

The fluid can be heated by an electronic device system. For example, a fluid in a cavity of heat exchanger 304 can be heated as heat is transferred from electronic device system 306. In some embodiments, the fluid can be cooled after being heated by heat transfer from an electronic device. The cooling system 318 can be remote or not contacting the electronic device system 306. For example, the fluid cooling system 318 may not be in thermal communication with the electronic device system 306 and/or heat exchanger 304. One or more tubes, channels, ducts, pipes, or other fluid transfer devices may connect heat exchanger 304 with the fluid cooling system 318 to transfer fluid between the heat exchanger 304 and the fluid cooling system 318.

Examples of coolant fluids can include distilled water, solutions including nanoparticles, gylcol mixture(s), and/or phase change materials. Fluid can be propelled through the system using a pump. Examples of liquids that can be used include, but are not limited to water. In some embodiments, the pump 328 can be coupled to the heat exchanger 304 and the fluid cooling system 318. Pump 328 can be used to circulate fluid from the heat exchanger 304 to the fluid cooling system 318 and back. By positioning the pump 328 in the path of the heated fluid rather than in the path where cooled fluid is passed from the fluid cooling system 318 to the heat exchanger 304, the impact of possible heat or losses imposed by the pump 328 is reduced and/or avoided. For example, in such a configuration, waste heat from the pump or fan may have a lower effect on the fluid in the heat exchanger 304. In some embodiments, the pump 328 may operate continuously. In other examples, the pump 328 can operate intermittently (e.g., a pulsatile or other periodic flow can be used). The pump 328 may include a motor. A speed of the motor may set a flow rate of the fluid in some embodiments. The motor can be controlled using pulse width modulation (PWM). Accordingly, the control system 310 may provide one or more PWM signals to the pump 328.

In some embodiments, the fluid cooling system 318 may set fluid properties based on the actual thermal load, the boundary conditions, and the electronic device system characteristics. In the example of FIG. 3, the fluid cooling system 318 can be positioned to receive heated fluid from an output of the heat exchanger 304, cool the fluid, and provide cooled fluid to an input of the heat exchanger 304. The thermoelectric device 312 can be in turn coupled to heat exchanger 308. The heat exchanger 302 can be positioned to receive fluid from heat exchanger 304. The heat exchanger 302 may cool the fluid. The fluid cooling system 318 can be proximate to the electronic device system 306 in some embodiments. In other examples, the fluid cooling system 318 can be remote from the electronic device system 306 (e.g., in a different rack than the electronic device system 306 and/or distanced from the electronic device system 306 such as in another device, and/or spaced apart in a room or other location).

To aid in cooling fluid, heat exchangers of a fluid cooling system described herein can be in thermal communication with one or more thermoelectric devices. For example, the heat exchanger 302 can be in thermal communication with thermoelectric device 312. A thermoelectric device refers to a device that may provide a thermal difference from one side to another responsive to an applied energy (e.g., an applied voltage and/or current). The thermoelectric device 312 may accordingly have a cold side and a hot side. The cold side generally refers to a portion of the device that may have a lower temperature than the other side of the device having a higher temperature. The difference in temperature between the hot side and the cold side can be based on an applied power (e.g., voltage and/or current). In some embodiments, an applied thermoelectric current can be set by the control system 310. The difference in temperature between the hot side and the cold side may in some embodiments be influenced by heat transfer from other devices to the hot and/or cold sides as well. Once energized, the thermoelectric device 312 can reduce a temperature of the fluid being circulated in the cooling system, transferring the heat to the heat exchanger 308 and through the heat exchanger 316 to the environment in some embodiments.

In some embodiments, electricity can be generated at least in part due to a thermal difference between the hot and cold sides of the thermoelectric device. For example, a thermoelectric device integrated into the heat exchanger 316 can be a thermoelectric generator used to generate electricity. In some embodiments, heat extracted from the fluid in heat exchanger 302 can be used to generate electricity by the thermoelectric device embedded in the heat exchanger 316. The thermoelectric device 312 can be used for cooling the fluid, while another thermoelectric device can be integrated into heat exchanger 316 and may perform heat recovery.

In the example of FIG. 3, the heat exchanger 302 can be in thermal communication with the cold side of the thermoelectric device 312. In this manner, heat can be extracted from a heated fluid flowing through the heat exchanger 302. In some embodiments, another heat exchanger (e.g., heat exchanger 308) can be in thermal communication with the thermoelectric device 312. The heat exchanger 308 can be in thermal communication with the hot side of the thermoelectric device 312.

In some embodiments, the heat exchanger 302 and heat exchanger 308 have geometries and/or materials that can be selected for a thermal impedance match between the heat exchanger 302 and heat exchanger 308 and/or thermoelectric device 312. For example, a surface area of a side of the heat exchanger 308 facing the heat exchanger 302 can be selected to be equal to the surface area of a side of the heat exchanger 302 facing the heat exchanger 308. Further, each component of the fluid cooling system 318 may exhibit a specific thermal resistance ratio which can depend on the operating conditions and the configuration. For instance, based on the thermoelectric device 312 and its thermal resistance, the heat exchanger 302 and heat exchanger 308 may include heat transfer coefficients that are equal and/or within a particular range and/or have a particular relationship with one another. This may facilitate heat flow in the system. The thermal resistance may depend on the geometry, flow rate, the manufacturing process (e.g., the surface roughness of the materials), and heat load from the electronic device system. Thermal impedance matching allows the temperature control of electronic device systems through a precise design of every component to maximize heat transfer.

For example, in a parallel channel heat exchanger, the size of each channel determines, at a specific flow rate, the heat transfer coefficient and/or its thermal resistance. The actual parameter is the hydraulic diameter, which can be equal to a ratio between area and wetted perimeter of the channel section. Hydraulic diameter and flow rate combined may wholly or in part define the thermal resistance. In some embodiments, the geometry and hydraulic diameter of a first heat exchanger (e.g., heat exchanger 302) can be selected to be a portion (e.g., half) of the thermal resistance of a thermoelectric device (e.g., thermoelectric device 312). Similar considerations can apply to heat exchanger 308. Accordingly, the two heat exchangers, heat exchanger 302 and heat exchanger 308 can be used to maintain a thermal gradient between the thermoelectric device 312 surfaces.

Further, in some embodiments, the control system 310 can be configured to receive a signal indicative of the temperature of the electronic device system 306, the control system 310 is configured to adjust a cooling supply comprising at least one of a flow rate and a temperature of the fluid at the first heat exchanger 302. In other words, the control system can be configured to match the cooling supply to the thermal output of the electronic device system 306. The cooling supply can include the flow rate and temperature of the cooling fluid, which can be determined by the control system 310. The cooling supply can be adjusted to dynamically match the thermal output of the electronic device system 306. In some embodiments, the control system 310 can be configured to predict the thermal output of the electronic device system 306. The control system 310 can then match the predicted value of the thermal output to the cooling supply. This dynamic matching can save energy and minimize overheating of the electronic device system 306. As noted above, the electronic device system 306 can include a microprocessor.

In some embodiments, thermoelectric device(s) in fluid cooling systems described herein can be operated wholly or partially as a generator. For example, using the Seebeck effect, the thermoelectric device embedded in the heat exchanger 316 may extract electrical power from heat. While commercial thermoelectric generator efficiency can be too modest, as the thermal gradient at the interfaces, to obtain substantial energy savings-however, some microprocessors present high heat flux. In some embodiments, such as instances where the electronic device system 306 can be implemented using multiple microprocessors in one or more server racks, economy of scale may offset the generator's low efficiency.

In some embodiments, another heat exchanger, such as heat exchanger 316 of FIG. 3 can be coupled to the heat exchanger 308. The heat exchanger 316 can be used to exchange waste heat with the environment. In some embodiments, the heat exchanger 316 may provide electrical power and/or energy generation based on the integrated thermoelectric generator. In some embodiments, an energy recovery system can be used to wholly and/or partially implement heat exchanger 316. The energy recovery system may include a thermoelectric generator that may convert all or portions of the heat flux from the heat exchanger 308 into electrical power. The amount of electrical power generated may depend on the thermal gradient between the thermoelectric generator's opposite surfaces and the heat load from the heat exchanger 308. In some embodiments, a power conditioner 330 may transform the electrical power into a power suitable for storage in energy storage 332, such as a battery pack. In some embodiments, the power conditioner 330 can be configured to protect against power surges and can be configured to monitor the power and condition it to keep it steady. The power conditioner maximizes the energy yield at various operating conditions. In some embodiments, the power conditioner 330 can change the electrical impedance to the energy recovery system in the heat exchanger 316 so that it captures the maximum power available. The power conditioner 330 can be implemented, for example, using circuitry or other devices to condition power generated from the heat exchanger 316 and/or the embedded thermoelectric device. The controller 314 may provide one or more control signals to aid in conditioning the power. In some embodiments, the power conditioner 330 may provide signals to the controller 314 to maximize power generation. The power conditioner 330 may provide power to one or more energy storage devices, such as energy storage 332. The energy storage 332 can be implemented using one or more batteries.

Systems described herein may include one or more temperature sensors. Temperature sensors can be provided to measure and/or monitor the temperature of certain components in the system. Components whose temperature can be monitored include an electronic device system, one or more heat exchangers, the fluid, and/or the thermoelectric device or particular sides of the thermoelectric device. In the example of FIG. 3, the system 300 includes temperature sensor 334, temperature sensor 336, and temperature sensor 338. The temperature sensor 334 can be positioned to measure a temperature of the electronic device system 306. The temperature sensor 336 can be positioned to measure a temperature of at least a side of the heat exchanger 302 facing the thermoelectric device 312 (e.g., the cold side of the thermoelectric device 312). The temperature sensor 338 can be positioned to measure a temperature of a side of the heat exchanger 308 facing the thermoelectric device 312 (e.g., the hot side of the thermoelectric device 312). Additional, fewer, and/or different temperature sensors can be used in other examples. In some embodiments, a temperature sensor can be positioned to measure a temperature of the fluid, for example at an input and/or output of heat exchanger 304 and/or heat exchanger 302. The temperature sensors 334, 336, and 338 can provide input into the control system to adjust the temperature and/or flow rate of the fluid used to cool the electronic device system 306.

Examples described herein may provide control of heat exchange using cooled fluids. For example, the rate of heat exchange and/or temperature of an electronic device system, such as electronic device system 306, can be controlled using control systems described herein. In some embodiments, the control system 310 may set a flow rate of the fluid and/or may set a power to a thermoelectric device. For example, the control system 310 may set an electric power to the thermoelectric device 312 and may set a flow rate of the pump 328, taking into consideration the electronic device system 306 characteristics, the temperature data from temperature sensor 334, temperature sensor 336, and/or temperature sensor 338, and/or the PWM duty cycle for the pump 328. In some embodiments, multiple temperature sensors may not be used. In some embodiments, only the temperature sensor 334 is used as input to control system 310. In the example of FIG. 3, control system 310 includes a controller 314, a driver 324, a driver 320, a driver 322, and a cache 326. The control system 310 may include one or more controllers, such as controller 314. Controllers can be implemented using, for example, one or more processors, microcontrollers, controllers, and/or circuitry. In some embodiments, controller 114 may additionally or instead be implemented using software and/or firmware. For example, computer-readable media (e.g., memory, storage, read-only memory (ROM), random access memory (RAM), solid-state drive (SSD), cache 326) can be encoded with instructions which, when executed by a controller (e.g., processor) may perform control methodologies described herein. In some embodiments, the control system 310 may store parameters (e.g., flow rate(s), driver signals, PWM settings, and/or thermoelectric current settings) for particular boundary conditions—e.g., for particular loads (such as particular electronic device systems) and/or temperatures. The parameters can be stored, for example in cache 326 or other memory accessible to the controller 314. During operation, the controller 314 can look up parameters for use by the driver 324 and/or other drivers based on a thermal load and/or boundary conditions of the system 300.

Drivers can be used by the control system 310 to provide a control signal to and/or influence the performance of particular components. For example, the driver 324 can be coupled to the pump 328. The controller 314 may provide control signal(s) to driver 324, and the driver 324 may accordingly provide a signal to the pump 328 to control operation of the pump 328—e.g., to start, stop, and/or moderate a speed of the pump 328.

The driver 322 can be coupled to the thermoelectric device 312. The controller 314 may provide control signal(s) to the driver 322, and the driver 322 may accordingly provide a signal to the thermoelectric device 312 to control operation of the thermoelectric device 312. For example, the control signal may increase and/or decrease a current applied to the thermoelectric device 312 (and/or a voltage applied across the thermoelectric device 312), and may accordingly change a temperature difference between the hot and cold side of the thermoelectric device 113.

The driver 320 can be coupled to the heat exchanger 316. The controller 314 may provide control signal(s) to the driver 320. The driver 320 may in turn provide a signal to the heat exchanger 316 to set and/or change a rate of heat transfer to the environment. In some embodiments, the driver 320 may provide a control signal to the heat exchanger 316 that may start, stop, and/or change a rate of electricity generation. In some embodiments, the driver 320 can change the electrical impedance to the energy recovery system in the heat exchanger 316 so that it captures the maximum power available.

Accordingly, to provide control of heat exchange in the system, the controller 314 may receive one or more temperature signals from or proximate components of the system. For example, the controller 314 may receive a signal indicative of a temperature of an electronic device system and/or a heat exchanger in thermal communication with the electronic device system (e.g., from temperature sensor 334). In some embodiments, the controller 314 may additionally or instead receive a signal indicative of a temperature of one or more components of a fluid cooling system (e.g., of heat exchanger 302 and/or heat exchanger 308, such as from temperature sensor 336 and/or temperature sensor 338).

The control systems 310 may receive a signal indicative of a temperature of an electronic device system, such as a temperature from temperature sensor 334. The control system 310, using controller 314, may compare the temperature to a predetermined temperature of the electronic device system 306. The predetermined temperature can be stored in a memory or other electronic storage accessible to controller 314 (e.g., cache 326). In some embodiments, the predetermined temperature can be represented by one or more threshold values (e.g., an upper limit temperature, a lower limit temperature, and/or a desired average temperature). Based on the comparison, the control system 310 may provide one or more control signals to components of the system 300 to adjust the temperature closer to the desired temperature and/or within one or more of the threshold values. For example, the control system 310 may provide control signals to the pump 328 and/or to the thermoelectric device 312 which may result in changes to the flow rate of the fluid and/or in a heat transfer coefficient at the heat exchanger 304 and/or heat exchanger 302. In this manner, overall heat transfer in the system can be controlled and adjusted. In some embodiments, a fluid temperature (e.g., as determined by power to thermoelectric device 312) and flow rate selected by the control system 310 can be selected to increase the heat transfer coefficient in the heat exchanger 304 at the electronic device system 306 thermal load. A temperature as measured by temperature sensor 334 can be controlled to remain below critical values (e.g., threshold values) regardless of the operating condition of the electronic device system 306.

During operation, the control system 310 may receive one or more temperature signals of components in the system 300. The control system 310 can adjust a flow rate of the fluid circulating between heat exchanger 304 and fluid cooling system 318 and/or a power to thermoelectric device 312 when the temperature signals indicate the system performance is outside one or more threshold values. The adjustment of the flow rate and/or power may modify a heat transfer coefficient of the heat exchanger 304 and/or heat exchanger 302 which may include the fluid. The adjustment can be made by the controller 314 and/or one or more drivers such that the temperature of the electronic device system 306 and/or another component of the system moves toward the one or more threshold temperatures. For example, the control system 310 can include an algorithm that considers a threshold for the fluid temperature and its rate of increase/decrease. The correlation between the two measurements defines how much power the thermoelectric device 312 and the control system 310 should deliver to the heat exchanger 304 to prevent overheating.

In some embodiments, a particular performance setting of the system 300 and/or control system 310 can be activated when the temperature of one or more components exceeds a predetermined threshold. For example, the performance setting can be indicative of a more extreme adjustment setting to be made by the controller 314 using the drivers when the temperature is beyond an allowable threshold. If the temperature remains outside of a particular threshold range and/or exceeds an allowable threshold (either high or low) for greater than a predetermined amount of time (e.g., an amount of time stored in an area accessible to the controller 314, such as cache 326), the control system 310 may trigger an alarm. The alarm can be an audible, tactile, or visual alarm, and/or may include a communication (e.g., an email, phone call, text, SMS message, etc.). The controller 314 can trigger and provide the alarm, such as by providing an alarm signal to one or more displays, communication interface(s), speakers, and/or other output device(s) in communication with the controller 314 and/or control system 310.

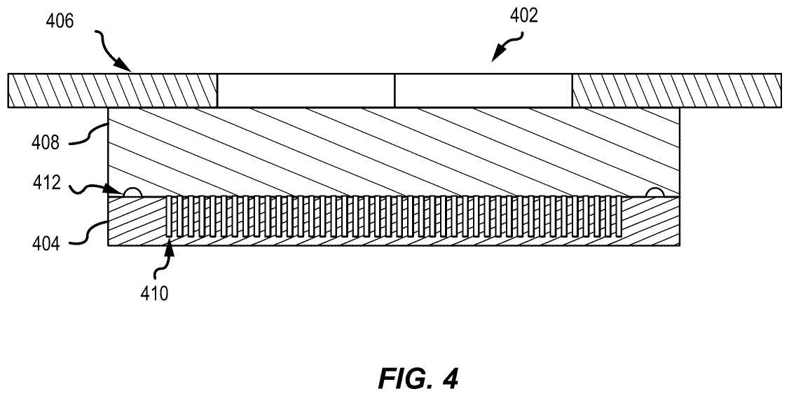

FIG. 4 is a partially schematic cross-sectional view of a heat exchanger 402 configured in accordance with embodiments of the present technology. The heat exchanger 402 includes a radiator block 404, a cover plate 406, and an insulating body 408. The radiator block 404 can include microchannels 410. An interface between insulating body 408 and radiator block 404 can be sealed using seal 412. The heat exchanger 402 can be used to implement and/or can be implemented by the heat exchanger 302, heat exchanger 304, and/or heat exchanger 308 of FIG. 3 as described above.

The radiator block 404 at least partially defines a cavity that fluid may flow within. In the example of FIG. 4, a cross-section of microchannels is shown, although other structures can be used. The microchannel architecture can be advantageous due to the wide range of operating conditions, high thermal loads, and limited envelope, which can be presented by an electronic device system to be cooled in accordance with embodiments of the present technology. In the microchannel architecture, overall surfaces may overlap standard microelectronic surfaces (e.g., 40×40 mm and higher). The structures (e.g., microchannels 410) can be formed and/or coated with high thermal conductivity material (e.g., thermal compound or pads). The section of FIG. 4 shows equally spaced straight channels. The microchannels may have sub-millimetric spacing in some embodiments. The use of microchannels (or other structures in other examples) may increase a surface area over which the fluid may transfer heat to the radiator block 404. Any microchannel geometries can be used, including straight, curved, intersecting, interrupted, and/or broken. Accordingly, the microchannel (or other structure) can be encapsulated in one or more thermally insulating layers. A channel can be provided in insulating body 408 to accommodate a seal, such as seal 412. The seal 412 can be implemented using, for example an O-ring and/or a gasket. The seal 412 may reduce and/or prevent fluid leakage. The cover plate 406 may secure the heat exchanger 402 to an electronic device system to be cooled, such as electronic device system 306 of FIG. 3.

Examples of heat exchangers described herein may accordingly include one or more structures. The structures may alter the flow of the fluid within the cavity, such as by creating one or more eddies. Any of a variety of structures can be used. In some embodiments, the structures include wavy channels.

FIG. 5 is a partially schematic isometric view of a heat exchanger 500 configured in accordance with embodiments of the present technology. As described herein with reference to heat exchanger 304, the heat exchanger 500 can include a cavity 510 and one or more structures 512 positioned wholly or partially in the cavity 510. The structures can affect a flow of the fluid in the cavity 510, such as by causing one or more eddies in the fluid flow. As a result, the heat exchanger 500 can cool the fluid (e.g., by extracting heat from the fluid due to convection and/or thermoelectric mechanisms) and/or expel heat into the fluid.

It is to be understood that the arrangement, shape, and pattern of the structures 512 can vary between embodiments. Additionally, the wall shape of the various features may vary (e.g., different individual structures can be straight, curved differently, have different thicknesses, and/or be sloped). Generally, the structures 512 can be selected to help increase an amount of surface area available to transfer heat between the heat exchanger 500 and the fluid flowing therethrough. However, the larger the surface, in some embodiments, the more friction the fluid may have at the channel walls. The fluid may then be slower, and the heat transfer process can become less efficient. Additionally, or alternatively, the structures 512 can be selected to create turbulence, eddies, and/or the like that increase fluid-wall interactions within the cavity 510, thereby increasing the amount of heat that is transferred between the heat exchanger 500 and the fluid flowing therethrough. Said another way, the geometry of the structures 512 and fluid speed (e.g., flow rates) are used herein to help control heat transfer between the heat exchanger 500 and the fluid flowing therethrough. In some embodiments, a larger pump can be selected to further increase flow rates, which may not be desirable due in part to larger size and/or larger power consumption.

In some embodiments, to design a cavity with structures, one or more cavity designs can be tested in a given system (e.g., with a particular electronic device system and/or heat exchangers, and/or cooling system), and a particular structure arrangement can be selected from the candidate structures and/or a new arrangement selected based on thermal load and flow rate(s) in the system. In some embodiments, the structures generate turbulence, eddies, and/or the like that can increase the heat transfer in a similar manner as heat transfer is increased in a turbulent flow regime. In some such embodiments, however, a general flow in the cavity 510 remains in a laminar flow regime. The increased heat transfer may occur even with a smaller heat transfer surface in some embodiments. The selection of geometry, topology, and mechanical properties, including roughness and tolerances, determines the thermal resistance. For example, the wavy channels can be machined with additive manufacturing to maximize heat exchange at a low flow rate.

Returning to the description of FIG. 3, control signals from the control system 310 (e.g., by controller 314 and/or any drivers of control system 310) can be based on fluid boundary conditions in the heat exchanger 304 (e.g., based on the structures 512 in the cavity 510 of FIG. 5). For example, fluid dynamics occurring in the heat exchanger 304 may affect heat transfer to the fluid. The structures present in a cavity defined by the heat exchanger 304 may, for example, generate eddies or other fluid patterns that may affect the heat transfer. The controller 314 may utilize the anticipated fluid pattern to determine one or more control signals. In some embodiments, control signals provided by the control system 310 may additionally or instead be based on a thermal load at the electronic device system 306. As the thermal load on an electronic device increases, a temperature of the electronic device system 306 may increase. Accordingly, the controller 314 may increase the flow rate of the fluid and/or increase power to the thermoelectric device 312 to transfer more heat from the electronic device system 306. Accordingly, the control system 310 can adjust a heat transfer coefficient between the fluid and one or more heat exchangers in the system (e.g., by adjusting the flow rate of the fluid and/or power to the thermoelectric device 312).

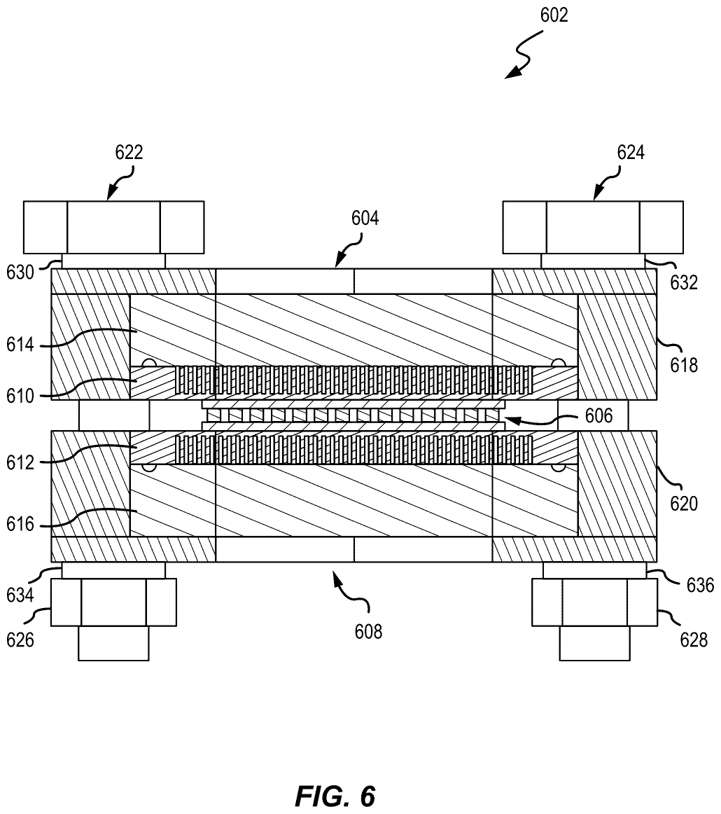

FIG. 6 is a partially schematic cross-sectional view of a fluid cooling system 602 configured in accordance with embodiments of the present technology. The fluid cooling system 602 includes an upper heat exchanger 604, a thermoelectric device 606, and a lower heat exchanger 608. The fluid cooling system 602 can be used to implement and/or can be implemented by the fluid cooling system 318 of FIG. 3 in some embodiments.

The upper heat exchanger 604 and lower heat exchanger 608 can include radiator blocks. For example, the heat exchanger 604 can include radiator block 610 and the heat exchanger 608 can include radiator block 612. The radiator blocks can define a cavity for fluid flow, and can include one or more structures (e.g., wavy microchannels). The radiator blocks can be encapsulated in one or more insulating layers. The heat exchanger 604 and heat exchanger 608 can include insulating bodies. For example, the heat exchanger 604 can include insulating body 614, which can include one or more insulating materials such as acrylic glass, or glass. Similarly, the heat exchanger 608 can include insulating body 616. In some embodiments, the fluid cooling system 602 includes another insulating body and/or layer. For example, the heat exchanger 604 can include insulating body 618 and the heat exchanger 608 can include insulating body 620, each of which forms form an outer body of the respective heat exchanger. Each element's geometry can be selected for thermal impedance matching.

The fluid cooling system 602 can be assembled using a compression method, which can be an example of a mechanical locking mechanism. The thermoelectric device 606 can be coupled to the heat exchanger 604 and heat exchanger 608 using compression members. For example, a bolt 622 can be secured to a nut 626 and bolt 624 can be secured to nut 628 at opposite ends of the assembly. Other numbers of bolts and/or nuts can be used in other examples.

Washers or other separators can be used to isolate components and reduce and/or prevent thermal short circuits. For example, the washer 630 can be positioned between bolt 622 and heat exchanger 604. The washer 632 can be positioned between bolt 624 and heat exchanger 604. The washer 634 can be positioned between nut 626 and heat exchanger 608. The washer 636 can be positioned between nut 628 and heat exchanger 608. In some embodiments, the washers may include thermally insulating washers.

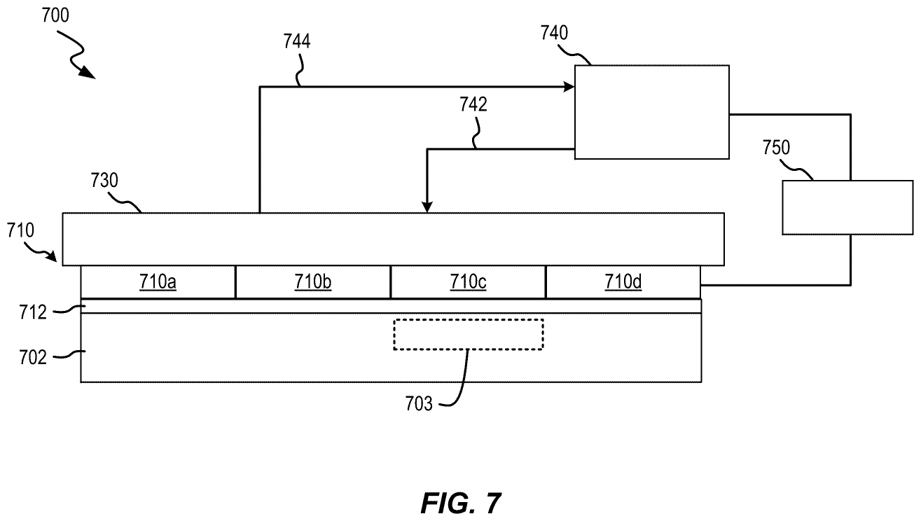

FIG. 7 is a block diagram of a system 700 with a localizable cooling subsystem configured in accordance with embodiments of the present technology. The system 700 (sometimes also referred to herein as a “cooling system”) is couplable to an electronic device 702 to help cool (e.g., remove heat) therefrom. The electronic device 702 can include one or more CPUs, GPUs, and/or other processing cores that can receive a workload during operation of a computing system and generate heat based on their respective workloads. As illustrated in FIG. 7, the system 700 can include a plurality of thermoelectric components 710 (four illustrated, referred to individually as first-fourth thermoelectric components 710a-710d). Similar to the systems discussed above, the thermoelectric components 710 have a cold side that is thermally coupled to electronic device 702 as well as a hot side that is thermally coupled to an external-facing heat exchanger 730. In the illustrated embodiment, however, the thermoelectric components 710 are each thermally coupled to (e.g., attached to) the electronic device 702 via a heat spreader 712. Said another way, the thermoelectric components 710 can be coupled to the electronic device 702 without a device-side liquid loop (e.g., coupled directly to the electronic device 702 via the heat spreader 712). The omission of the internal liquid loop can help simplify the operation of the system 700, omit a potential source of failure from systems that require the internal liquid loop, and/or help accelerate a response of the system 700 to a thermal load at the electronic device 702. For example, the thermoelectric components 710 can create a temperature gradient directly between an external surface of the electronic device 702 and the external-facing heat exchanger 730, thereby transporting heat directly from the electronic device 702 into the external-facing heat exchanger 730. Because the temperature gradient is created directly at the external surface of the electronic device 702, there is no lag time associated with the flow of fluid and/or transfer of heat in and/or out of the fluid.

As further illustrated in FIG. 7, the system 700 can include an external cooling component 740 and a controller 750. The external cooling component 740 (e.g., an external liquid loop) is fluidly coupled to the external-facing heat exchanger 730 via an input channel 742 and an output channel 744. The external cooling component 740 can include a liquid loop that is generally similar to the liquid loops discussed above. For example, the external cooling component 740 can include one or more heat syncs, one or more active cooling components, one or more pumps, and/or the like to drive a flow of fluid through the input and output channels 742, 744. As a result, the external cooling component 740 can help transport heat away from the external-facing heat exchanger 730, allowing the system 700 to effectively remove heat from the electronic device 702.

The controller 750 is operably coupled to the thermoelectric components 710 and the external cooling component 740 to control various operating parameters of the system 700. For example, similar to the discussion above, the controller 750 can set and/or deliver an electric current to one or more of the thermoelectric devices to generate and/or control the temperature gradient (and therefore the amount of active cooling delivered to the electronic device 702). Additionally, or alternatively, the controller 750 can control a speed of one or more pumps in the external cooling component 740 control the amount of heat removed from the external-facing heat exchanger 730.

As further illustrated in FIG. 7, the electronic device 702 can have one or more hot spots 703 (one illustrated in FIG. 7). The hot spot 703 can correspond to a CPU/GPU (or other processing unit) that has a temperature above a threshold temperature (e.g., a maximum value before thermal throttling kicks in to reduce the chance of damage to the electronic device 702). While the system 700 is positioned to be able to cool the electronic device 702, doing so would be inefficient because the hot spot 703 is isolated to only a portion of the electronic device 702. Instead, the system 700 (e.g., via the controller 750 and/or another suitable device) can operate only a subset of the plurality of the thermoelectric components 710 that correspond to the hot spot 703. In the illustrated scenario, for example, the system 700 can operate only the third thermoelectric component 710c, thereby delivering cooling only to the portion of the electronic device 702 corresponding to the hot spot 703. As a result, the system 700 can help effectively cool the CPUs/GPUs (and/or other processing units) in the electronic device 702 as needed, while reducing the overall energy required to deliver the cooling. That is, by delivering cooling only to the hot spots 703, the system 700 can help increase an efficiency of the cooling operation.

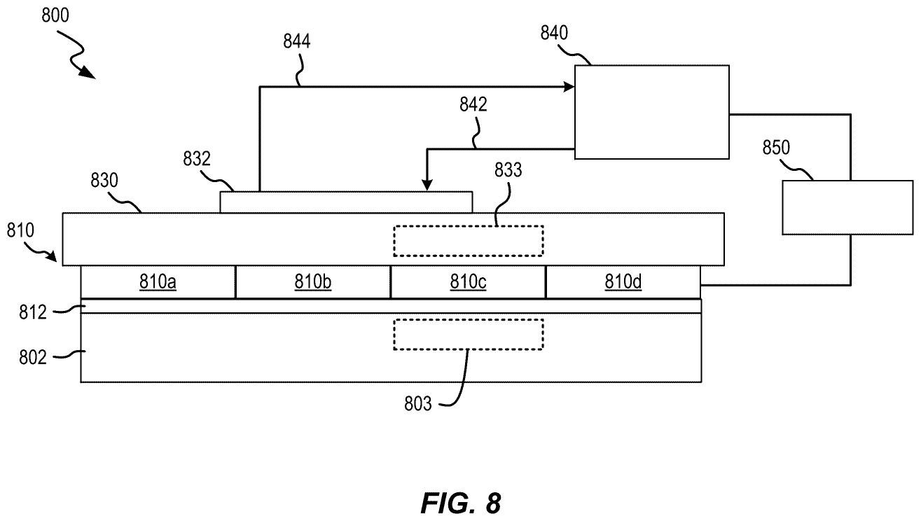

FIG. 8 is a block diagram of a system 800 with a localizable cooling subsystem configured in accordance with further embodiments of the present technology. As illustrated in FIG. 8, the system 800 can be generally similar to the system 700 discussed above with reference to FIG. 7. For example, as illustrated in FIG. 8, the system 800 includes a plurality of thermoelectric components 810 that are each thermally coupled to an electronic device 802 via a spreader 812. Further, the system 800 includes an external-facing heat exchanger 830 thermally coupled to the plurality of thermoelectric components 810, an external cooling component 840 fluidly coupled to the external-facing heat exchanger 830 via an input channel 842 and an output channel 844, and a controller 850 operably coupled to the plurality of thermoelectric components 810 and the external cooling component 840.

Still further, as illustrated in FIG. 8, the electronic device 802 can include one or more hot spots 803 (one illustrated in FIG. 8), corresponding to a processing unit with a temperature that exceeds a threshold temperature. Similar to the discussion above, the system 800 can respond to the hot spot 803 by operating only a subset of the plurality of thermoelectric components 810. For example, the system can operate only the third thermoelectric component 810c (e.g., while the first, second, and fourth thermoelectric components 810a, 810b, 810d remain inactive). As a result, the system 800 can deliver cooling to the hot spot 803 of the electronic device 802 while reducing the power consumed by the system 800 overall.

As further illustrated in the embodiments of FIG. 8, the system 800 can include a valve component 832 fluidly coupled between the external-facing heat exchanger 830 and the external cooling component 840. The valve component 832 can direct (or block, obstruct, and/or prevent) incoming fluid to a subregion 833 of the external-facing heat exchanger 830, such as a hot spot corresponding to the third thermoelectric component 810c. Said another way, the valve component 832 can be operable between various positions that allow the fluid to flow through a portion of the heat exchanger 830 corresponding to one of the thermoelectric components 810 and various positions that prevent the fluid from flowing through the portions of the heat exchanger 830 corresponding one of the thermoelectric components 810. As a result, rather than pumping fluid through the entirety of the external-facing heat exchanger 830, the external cooling component 840 can pump a liquid only through the subregion 833, thereby reducing the amount of the external-facing heat exchanger 830 that the external cooling component 840 is actively cooling. Said another way, the system 800 can isolate the cooling from the external cooling component 840 to only the subregion 833 of the external-facing heat exchanger 830 that receives heat from the hot spot 803. As a result, the system 800 can further reduce the power required to deliver cooling to the electronic device 802, thereby improving the overall efficiency of the system 800.

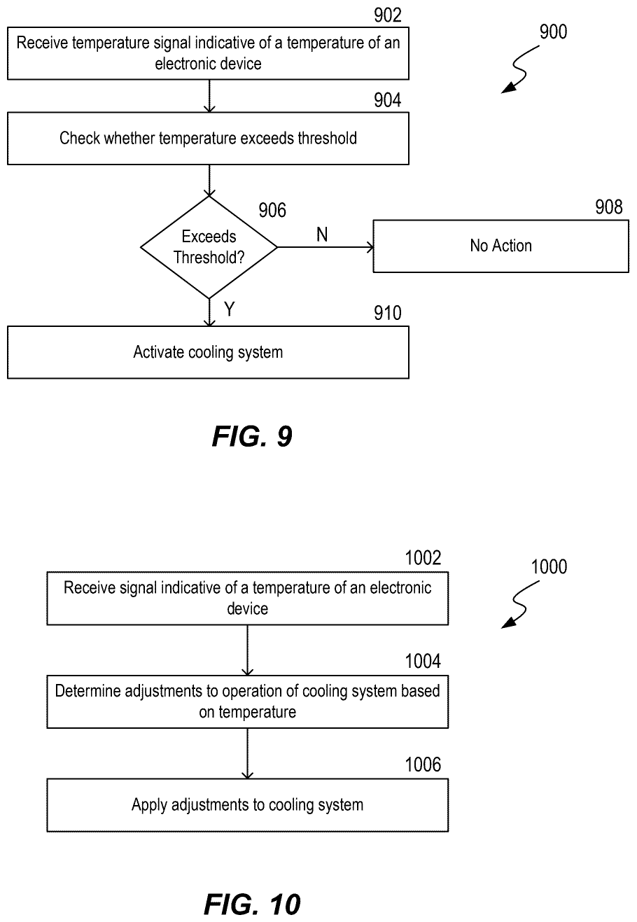

FIG. 9 is a flow diagram of a process 900 for operating a cooling subsystem in accordance with further embodiments of the present technology. More specifically, the process 900 can be executed to allow a cooling system to respond to changes in temperature in an electronic device. The process 900 can be executed by a controller of a cooling system, such as the ECUs 104 and/or the CCU 112 of FIG. 1, the controller 314 of FIG. 3, the controller 750 of FIG. 7, the controller 850 of FIG. 8, and/or any other suitable device. Further, although discussed below primarily in the context of being implemented by a single processing component, one of skill in the art will understand that the process 900 is not so limited. Instead, the process 900 can be implemented by two or more processing components working in conjunction. Purely by way of example, the process 900 can be split between the ECUs 104 and the CCU 112 of FIG. 1.

The process 900 begins at block 902 by receiving a temperature signal that is indicative of a temperature in an electronic device. The temperature signal can be received from one or more thermal sensors integrated with the electronic device, one or more thermal sensors coupled to the electronic device, and/or any other suitable source. In some embodiments, the temperature signal is an estimate of the temperature based on a workload assigned to processing units in the electronic device (e.g., based on a map between workloads and expected temperatures). In some embodiments, the temperature signal is specific to one or more individual processing units in the electronic device. For example, in a device with two or more CPUs (e.g., two or more CPU cores in a supercomputer), the temperature signal can be specific to a subset of one or more of the processing units.

At block 904, the process 900 includes checking whether the temperature exceeds a threshold temperature. As discussed above, the threshold temperature can be a preset from a user (e.g., indicating a maximum temperature they prefer) and/or a preset from the electronic device (e.g., a manufacturer-set threshold for maximum temperature before thermal throttling occurs). Additionally, or alternatively, the temperature threshold can be variable. For example, a first computing operation can be time-sensitive such that no thermal throttling is acceptable while a second computing operation is not time-sensitive. In this example, the threshold for the first computing operation can be lower than the threshold for the second operation. The lower threshold can prompt intervention from a cooling system earlier in the first computing operation while the higher threshold can conserve energy for the second computing operation. In another example, the threshold temperature can vary between different processing units based on their operating capabilities (e.g., preset capabilities, measured temperature sensitivity, and/or the like). In yet another example, the temperature can vary over time for individual processing units as their operating abilities (and/or the cooling abilities of a cooling system) are measured and tracked. Accordingly, in some embodiments, the process 900 at block 904 includes checking the threshold relevant to the processing units involved.

At decision block 906, if the temperature is not above the threshold, the process 900 continues to block 908 to take no action. Conversely, if the temperature is above the threshold, the process 900 continues to block 910.

At block 910, the process 900 includes activating a cooling system. The cooling system can be generally similar (or identical) to any of the cooling systems discussed above. Accordingly, the process 900 at block 910 can include delivering an electric current to one or more thermal electric devices in the cooling system and/or starting fluid flow through one or more loops via one or more pumps. In some embodiments, the process 900 at block 910 is specific to detected hot spots (e.g., when the temperature of a first CPU is above the threshold while the temperature of a second CPU is not). In such embodiments, for example, the process 900 at block 910 can activate only a portion of the cooling system corresponding to the hot spot (e.g., only the first pre-cooling chamber 103a of FIG. 1, only the third thermoelectric component 710c of FIG. 7, and/or the like). In some embodiments, activating the cooling system at block 910 includes identifying operating conditions specific to the temperature received at block 902. That is, the activation can choose the starting operating parameters (e.g., drive current at the thermoelectric devices, flow rates of pumps, and/or the like) specific to current temperature conditions. As a result, for example, a first set of operating parameters can be chosen for a first temperature (e.g., just above the threshold) and a second set of operating parameters can be chosen for a second, higher temperature. In this example, the second set of operating parameters can be expected to remove more heat from the electronic device. By varying the starting operating parameters, the process 900 can allow the cooling system to quickly respond to thermal conditions while reducing the overall energy consumed by the cooling system.

FIG. 10 is a flow diagram of a process 1000 for operating a cooling subsystem in accordance with further embodiments of the present technology. More specifically, the process 1000 can be executed to adjust a cooling system to respond to changes in temperature in an electronic device after activating a cooling system (e.g., via the process 900 of FIG. 9). Similar to the process 900 discussed above with reference to FIG. 9, the process 1000 can be executed by a controller of a cooling system, such as the ECUs 104 and/or the CCU 112 of FIG. 1, the controller 314 of FIG. 3, the controller 750 of FIG. 7, the controller 850 of FIG. 8, and/or any other suitable device. Further, although discussed below primarily in the context of being implemented by a single processing component, one of skill in the art will understand that the process 1000 is not so limited. Instead, the process 1000 can be implemented by two or more processing components working in conjunction. Purely by way of example, the process 1000 can be split between the ECUs 104 and the CCU 112 of FIG. 1.

The process 1000 can begin at block 1002 by receiving a signal that is indicative of a temperature in an electronic device. Similar to the discussion above, the signal can include a direct temperature measurement received from one or more thermal sensors integrated with the electronic device, one or more thermal sensors coupled to the electronic device, and/or any other suitable source. Additionally, or alternatively, the signal can include a workload assigned to one or more processing units of the electronic device, an estimate of the temperature based on the assigned workload(s) (e.g., based on a map between workloads and expected temperatures), and/or the like. In some embodiments, the signal is specific to one or more individual processing units in the electronic device. For example, in a device with two or more CPUs (e.g., two or more CPU cores in a supercomputer), the signal can be specific to a subset of one or more of the processing units.

At block 1004, the process 1000 includes determining one or more adjustments to operation of the cooling system (e.g., adjustments to operating parameters) based on the temperature. As discussed above, the adjustments can include increasing or decreasing the operation of an active cooling component (e.g., adjustments to an electrical signal to one or more thermoelectric devices); adjustments to a drive signal at one or more pumps (e.g., to increase or decrease the flow of fluid); activating or deactivating one or more active cooling components; and/or the like. The adjustments can account for changes in the workload at any of the processing units in the electronic device (e.g., additional workload, completion of a task, etc.), measured changes in temperature (e.g., increases in temperature above an expected amount for a given workload), and/or various other changes in the operation of the electronic device. Additionally, or alternatively, the adjustments can be responsive to variations in the importance and/or time-dependence of computing tasks (e.g., an increase in priority of a computing task), variations in user-set values (e.g., a user changing a target temperature for the processing devices), variations in power-saving priorities (e.g., reducing cooling power when reducing power consumption increases in priority), and/or any other suitable variations. The adjustments can be determined via a look-up table and/or similar schedule that maps operating parameters, temperatures, computing power, and/or power consumption. Additionally, or alternatively, the adjustments can be determined by the temperature-modeling component. In a specific, non-limiting example, the adjustments can be determined by a learning model that is trained on data from past performances of the electronic device in response to various operating parameters of the cooling system and/or past performances of generally similar systems. Additionally, or alternatively, the adjustments can be determined in response to manual inputs into the system (e.g., from a user).

At block 1006, the process 1000 includes applying the adjustments to the cooling system. That is, for example, the process 1000 includes applying (or instructing another component to apply) the adjustments to the electric currents delivered to one or more thermoelectric devices; adjusting (or instructing another component to adjust) the operating parameters of a pump; and/or the like.

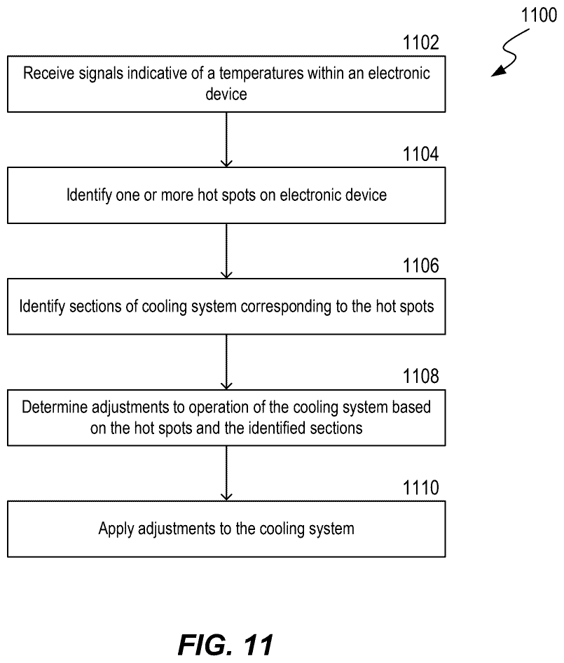

FIG. 11 is a flow diagram of a process 1100 for operating a cooling subsystem in accordance with further embodiments of the present technology. More specifically, the process 1100 can be executed to adjust a cooling system to respond to changes in temperature in an electronic device. Similar to the processes 900, 1000 discussed above with reference to FIGS. 9 and 10, the process 1100 can be executed by a controller of a cooling system, such as the ECUs 104 and/or the CCU 112 of FIG. 1, the controller 314 of FIG. 3, the controller 750 of FIG. 7, the controller 850 of FIG. 8, and/or any other suitable device. Further, although discussed below primarily in the context of being implemented by a single processing component, one of skill in the art will understand that the process 1100 is not so limited. Instead, the process 1100 can be implemented by two or more processing components working in conjunction. Purely by way of example, the process 1100 can be split between the ECUs 104 and the CCU 112 of FIG. 1.

The process 1100 begins at block 1102 by receiving signals that are indicative of temperatures in an electronic device. Similar to the discussion above, the signals can include a direct temperature measurement received from one or more thermal sensors integrated with the electronic device, one or more thermal sensors coupled to the electronic device, and/or any other suitable source. Additionally, or alternatively, the signals can include a workload assigned to processing units of the electronic device, an estimate of the temperature based on the assigned workloads (e.g., based on a map between workloads and expected temperatures), and/or the like. That is, the signals can be associated with a prediction of the temperature (and/or allow the process 1100 to predict a future temperature) based on the workload assigned to the processing units. In such embodiments, the process 1100 can be executed before the predicted temperature change actually occurs, such that the adjustments discussed below are made in anticipation of an increased thermal load. Said another way, the process 1100 can be executed ahead of actual changes in temperature to make anticipatory adjustments, thereby allowing the process 1100 to be ahead of any potential thermal throttling. Further, as discussed above, the signals can be specific to one or more individual processing units in the electronic device. For example, in a device with two or more CPUs (e.g., two or more CPU cores in a supercomputer), the signal can be specific to a subset of one or more of the processing units.

At block 1104, the process 1100 includes identifying one or more hot spots (e.g., the hot spot 703 of FIG. 7) within the electronic device. The hot spots are regions (e.g., CPU cores, processing units, sets of processing units, and/or the like) that have a temperature that is above a predetermined threshold for the corresponding region. As discussed above, the threshold can include a preset from a user and/or a preset from the electronic device. Additionally, or alternatively, the threshold can be variable. For example, the threshold can be based on the characteristics of processing units in the region, computing operations assigned to the processing units, energy-saving goals for the system, and/or the like. In embodiments where the signals are associated with workloads assigned to the processing units, the process 1100 at block 1104 can include predicting hot spots based on the workload, current temperatures, and/or characteristics of each of the processing units (e.g., how different processing units respond to different workloads).

At block 1106, the process 1100 includes identifying sections of the cooling system corresponding to the hot spots. For example, with reference to FIG. 1, if the hot spots include the second electronic component 101b, the section of the cooling system corresponding to the hot spot includes the corresponding pre-cooling chamber 103b. In another example, with reference to FIG. 7, if the hot spots include the hot spot 703, the section of the cooling system corresponding to the hot spot includes the third thermoelectric component 710c. In some embodiments, the sections of the cooling system corresponding to the hot spots include various adjacent sections. For example, returning to the example of FIG. 7, the section of the cooling system corresponding to the hot spot can include the second thermoelectric component 710b and/or the fourth thermoelectric component 710d.

At block 1108, the process 1100 includes determining adjustments to the operation of the cooling system based on the hot spots and the identified sections. That is, the process 1100 includes determining adjustments to the operating parameters (including whether the sections of the cooling system are operating at all) of the cooling system associated with the identified sections based on the current operating parameters, the temperatures in the hot spots, and/or any other suitable information. As discussed above, the adjustments can include increasing or decreasing the operation of an active cooling component (e.g., adjustments to an electrical signal to one or more thermoelectric devices); adjustments to a drive signal at one or more pumps (e.g., to increase or decrease the flow of fluid); activating or deactivating one or more active cooling components; and/or the like. Further, the adjustments can be determined via a look-up table and/or similar schedule that maps operating parameters, temperatures, computing power, and/or power consumption. Additionally, or alternatively, the adjustments can be determined by temperature-modeling component and/or in response to manual inputs into the system (e.g., from a user).

At block 1110, the process 1100 includes applying the adjustments to the cooling system. That is, for example, the process 1000 includes applying (or instructing another component to apply) the adjustments to the electric currents delivered to one or more thermoelectric devices; adjusting (or instructing another component to adjust) the operating parameters of a pump; and/or the like.

Examples of Suitable Computer Systems for Operating a Cooling Subsystem in Accordance with Embodiments of the Present Technology

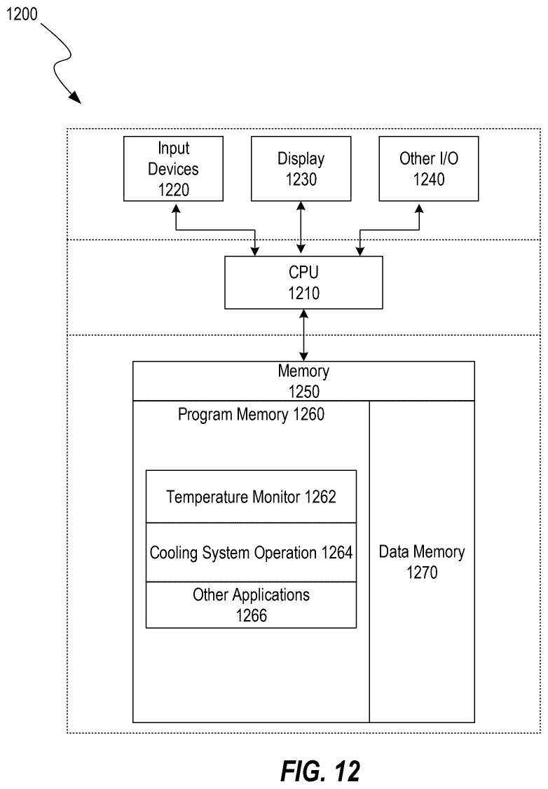

FIG. 12 is a block diagram illustrating an overview of an example of a device 1200 on which some embodiments of the present technology can operate. Purely by way of example, the device 1200 can operate the ECU 104 and/or the CCU 112 of FIG. 1 to implement various controls related to managing the temperature of various CPU/GPU cores. In the illustrated embodiment, device 1200 includes one or more input devices 1220 that provide input to one or more CPU(s) (processor, “the CPU”) 1210, notifying it of actions. The actions can be mediated by a hardware controller that interprets the signals received from the input devices 1220 and communicates the information to the CPU 1210 using a communication protocol. Input devices 1220 include, for example, a mouse, a keyboard, a touchscreen, an infrared sensor, a touchpad, a wearable input device, a camera- or image-based input device, a microphone, one or more temperature sensors, or other suitable user input devices.

The CPU 1210 can be a single processing unit or multiple processing units in a device or distributed across multiple devices. CPU 1210 can be coupled to other hardware devices, for example, with the use of a bus, such as a PCI bus or SCSI bus. The CPU 1210 can communicate with a hardware controller for devices, such as for a display 1230. The display 1230 can be used to display text and graphics. In some embodiments, the display 1230 provides graphical and textual visual feedback to a user. In some embodiments, the display 1230 includes the input device as part of the display, such as when the input device is a touchscreen or is equipped with an eye direction monitoring system. In some embodiments, the display is separate from the input device. Examples of display devices include an LCD display screen, an LED display screen, an OLED display screen, an AMOLED display screen, a projected, holographic, or augmented reality display (such as a heads-up display device or a head-mounted device), and so on. Other I/O devices 1240 can also be coupled to the processor, such as a network card, video card, audio card, USB, firewire or other external device, camera, printer, speakers, CD-ROM drive, DVD drive, disk drive, Blu-Ray device, one or more temperature sensors, and the like.

In some embodiments, the device 1200 also includes a communication device capable of communicating wirelessly or wire-based with a network node. The communication device can communicate with another device or a server through a network using, for example, TCP/IP protocols, a Q-LAN protocol, or others. Device 1200 can utilize the communication device to distribute operations across multiple network devices.

The CPU 1210 can have access to a memory 1250 in a device or distributed across multiple devices. A memory includes one or more of various hardware devices for volatile and non-volatile storage, and can include both read-only and writable memory. For example, a memory can comprise random access memory (RAM), various caches, CPU registers, read-only memory (ROM), and writable non-volatile memory, such as flash memory, hard drives, floppy disks, CDS, DVDS, magnetic storage devices, tape drives, device buffers, and so forth. A memory is not a propagating signal divorced from underlying hardware; a memory is thus non-transitory. Memory 1250 can include program memory 1260 that stores programs and software, such as a Temperature Monitoring component 1262, a Cooling System Operation component 1264, and other application programs 1266. Memory 1250 can also include data memory 1270 that can store data to be operated on by applications, configuration data, settings, options or preferences, etc., which can be provided to the program memory 1260 or any element of the device 1200.

Some embodiments can be operational with numerous other computing system environments or configurations. Examples of computing systems, environments, and/or configurations that can be suitable for use with the technology include, but are not limited to, sets of personal computers, loudspeakers, supercomputer systems, server computing systems, datacenter systems, AVC I/O systems, networked peripherals devices, server computers, handheld or laptop devices, cellular telephones, wearable electronics, gaming consoles, tablet devices, multiprocessor systems, microprocessor-based systems, set-top boxes, programmable consumer electronics, network PCs, minicomputers, mainframe computers, distributed computing environments that include any of the above systems or devices, or the like.

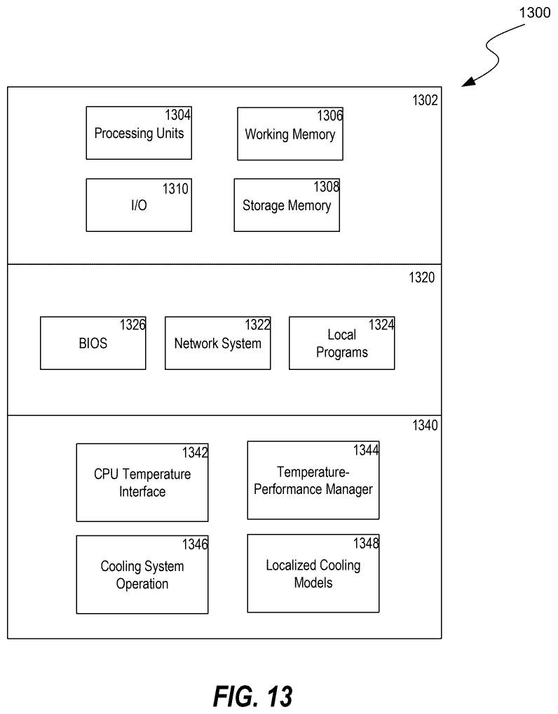

FIG. 13 is a block diagram illustrating components 1300 of a computing device configured in accordance with some embodiments of the present technology. The components 1300 include hardware 1302, general software 1320, and specialized components 1340. As discussed above, a system implementing the disclosed technology can use various hardware including processing units 1304 (e.g., CPUs, GPUs, APUs, etc.), working memory 1306, storage memory 1308 (local storage or as an interface to remote storage, such as various cloud storage devices), and input and output (I/O) devices 1310. In various embodiments, storage memory 1308 can be one or more of local devices, interfaces to remote storage devices, or combinations thereof. For example, storage memory 1308 can be a set of one or more hard drives (e.g., a redundant array of independent disks (RAID)) accessible through a system bus or can be a cloud storage provider or other network storage accessible via one or more communications networks (e.g., a network accessible storage (NAS) device). The components 1300 can be implemented in a client computing device and/or on a server computing device.

The general software 1320 can include various applications including a user interface 1322, local programs 1324, and a basic input output system (BIOS) 1326. In some embodiments, the specialized components 1340 can be subcomponents of one or more of the applications of the general software 1320. As illustrated in FIG. 13, the specialized components 1340 can include a CPU temperature interface 1342, a temperature-performance manager component 1344, a cooling system operation component 1346, and a localized cooling models component 1348. In some embodiments, the components 1300 can be in a computing system that is distributed across multiple computing devices or can be an interface to a server-based application executing one or more of specialized components 1340.

The CPU temperature interface 1342 can be coupled to one or more temperature sensors to receive signals related to the temperature of one or more CPU/GPU devices, as well as to the user interface 1322. The CPU temperature interface 1342 can use the signals to determine a temperature of the one or more CPU/GPU devices, identify one or more hot spots in the CPU/GPU devices, and/or help monitor for an increase in temperature above a threshold. As discussed above, the threshold can be predetermined (e.g., a preset temperature from a manufacturer, from a user of the device with the components 1300, and/or the like), can be determined from a preset performance requirement, and/or can vary based on a measurement of performance vs temperature over time. The CPU temperature interface 1342 can make the temperature(s) available to other components in the device with the components 1300, such as the user interface 1322 (e.g., for display to a user) and/or any of the other the specialized components 1340.

The temperature-performance manager component 1344 can be coupled to the can be coupled to one or more temperature sensors to receive signals related to the temperature of one or more CPU/GPU devices and/or various other components of the system (e.g., a workload manager for the one or more CPU/GPU devices). The temperature-performance manager component 1344 can monitor, record, and/or study a relationship between the workload applied to each of the one or more CPU/GPU devices and the resulting temperatures (and/or thermal load) in the one or more CPU/GPU devices. The temperature-performance manager component 1344 can then generate a model and/or map between the workload and an expected temperature (and/or thermal load). Additionally, or alternatively, the temperature-performance manager component 1344 can monitor, record, and/or study a relationship between the temperature (and/or thermal load) in each of the one or more CPU/GPU devices and performance metrics (e.g., refresh rates, computing rates, whether they required thermal throttling, and/or the like). The temperature-performance manager component 1344 can then generate a model and/or map between the temperature (and/or thermal load) and the performance metrics. The model and/or map can be used to help set a threshold temperature for a cooling system based on various goals (e.g., to minimize impact on computing rates, to balance computing power and energy demand, to avoid thermal throttling, and/or the like).

The cooling system operation component 1346 can be operably coupled to the CPU temperature interface 1342, the temperature-performance manager component 1344, the user interface 1322, and/or various components of the cooling system. For example, the cooling system operation component 1346 can be operably coupled to each active cooling device, pump, temperature sensor, and/or other component in the cooling system to set, adjust, read, and/or otherwise manage operating parameters at each of the components. In some embodiments, the cooling system operation component 1346 is operably coupled to the components of the cooling system via one or more intermediate components (e.g., the ECUs 104 of FIG. 1) to instruct the intermediate components on how to operate the components of the device. As discussed above, the operating parameters (and adjustments thereto) can be based on a measured temperature, expected temperature, workload, temperature threshold, energy consumption requirements, and/or the like for each processing unit in a computing system.

The localized cooling models component 1348 can be operably coupled to the CPU temperature interface 1342, the temperature-performance manager component 1344, the cooling system operation component 1346, and/or the user interface 1322. For example, the localized cooling models component 1348 can generate models and/or maps of operating parameters for the cooling system and the temperature and/or impact on the temperature in specific (e.g., targeted) processing units in a computing system. The localized cooling models component 1348 (and/or another suitable component) can then use the models and/or maps to identify operating parameters for the cooling system, specific to individual regions and/or processing units, based on a measured and/or expected temperature and various goals for managing the temperature.

Those skilled in the art will appreciate that the components illustrated in FIGS. 12 and 13 described above, as well as in each of the flow diagrams discussed above, can be altered in a variety of ways. For example, the order of the logic can be rearranged, substeps can be performed in parallel, illustrated logic can be omitted, other logic can be included, etc. In some embodiments, one or more of the components described above can execute one or more of the processes described below.

### EXAMPLES

The present technology is illustrated, for example, according to various aspects described below. Various examples of aspects of the present technology are described as numbered examples (1, 2, 3, etc.) for convenience. These are provided as examples and do not limit the present technology. It is noted that any of the dependent examples can be combined in any suitable manner, and placed into a respective independent example. The other examples can be presented in a similar manner.

1. A cooling system for removing heat from an electronic device comprising two or more processing units, the cooling system comprising:
a first thermoelectric component having a first cold side and a first hot side, wherein the first cold side is thermally couplable to a first processing unit from the two or more processing units;
a second thermoelectric component having a second cold side and a second hot side, wherein the second cold side is thermally couplable to a second processing unit from the two or more processing units, and wherein the second thermoelectric component is operable independent from the first thermoelectric component;
a heat exchanger thermally coupled the first hot side of the first thermoelectric component; and
an external cooling loop, the external cooling loop comprising:
   an input channel fluidly coupled to the heat exchanger to deliver a fluid at a first temperature to a channel within the heat exchanger; and
   an output channel fluidly coupled to the heat exchanger to receive the fluid from the channel at a second temperature higher than the first temperature.

2. The cooling system of example 1, wherein the heat exchanger is further thermally coupled to the second hot side of the second thermoelectric component.

3. The cooling system of any of examples 1 and 2, wherein:
the heat exchanger is a first heat exchanger with a first cavity, the input channel is a first input channel, and the output channel is a first output channel;
the cooling system further comprises a second heat exchanger thermally coupled to the second hot side of the second thermoelectric component; and
the external cooling loop further comprises:
   a second input channel fluidly coupled to the second heat exchanger to deliver a second fluid at the first temperature to a second channel within the second heat exchanger; and
   a second output channel fluidly coupled to the second heat exchanger to receive the fluid from the channel at a third temperature higher than the first temperature.

4. The cooling system of any of examples 1-3 wherein the heat exchanger is a hot-side heat exchanger, wherein the input channel is an external input channel, wherein the output channel is an external output channel, and wherein the cooling system further comprises:
a cold-side heat exchanger thermally coupled to the first cold side of the first thermoelectric component; and
an internal cooling loop thermally couplable between the cold-side heat exchanger and the first processing unit, the internal cooling loop comprising:
   an internal heat exchanger positionable in thermal contact with the first processing unit;
   an internal input channel, the internal input channel fluidly coupled between the cold-side heat exchanger and the internal heat exchanger to transfer a cooling fluid from the cold-side heat exchanger to the internal heat exchanger; and
   an internal output channel, the internal output channel fluidly coupled between the internal heat exchanger and the cold-side heat exchanger to transfer the cooling fluid from the internal heat exchanger to the cold-side heat exchanger.

5. The cooling system of example 4 wherein the internal cooling loop further comprises a pump fluidly coupled to the internal input channel and/or the internal output channel to control a flow rate of the fluid.

6. The cooling system of any of examples 1-3 wherein the first thermoelectric component is in thermal contact with a surface of the electronic device.

7. The cooling system of any of examples 1-6 wherein:
the heat exchanger includes a valve component fluidly coupled to the input channel; and
the valve component is operable between a first position and a second position, wherein:
   in the first position, the valve component allows the fluid to flow through a portion of the heat exchanger corresponding to the first thermoelectric component; and
   in the second position, the valve component prevents the fluid from flowing through the portion of the heat exchanger corresponding to the first thermoelectric component.

8. The cooling system of any of examples 1-7, further comprising a controller operably coupled to the first thermoelectric component and the second thermoelectric component, wherein the controller is configured to independently drive the first thermoelectric component and the second thermoelectric component in response to temperatures in the first processing unit and the second processing unit.

9. The cooling system of any of examples 1-8, further comprising a controller comprising a processor and a memory storing instructions that, when executed by the processor, cause the controller to:
receive signals indicative of a first temperature in the first processing unit and a second temperature the second processing unit;
determine, based on the first temperature and the second temperature, one or more adjustments to operating parameters of the first thermoelectric component and the second thermoelectric component, wherein the one or more adjustments alter a cooling power delivered by the first thermoelectric component and the second thermoelectric component; and
apply the one or more adjustments to the operating parameters to the first thermoelectric component and the second thermoelectric component.

10. The cooling system of example 9 wherein the one or more adjustments are based on:
a first comparison between the first temperature and a first threshold temperature for the first processing unit; and
a second comparison between the first temperature and a second threshold temperature for the second processing unit.

11. A method for operating a cooling system for removing heat from an electronic system, the method comprising:
receiving one or more signals associated with a temperature at each of a plurality of locations in the electronic system, each of the plurality of locations comprising one or more processing devices;
identifying one or more hot spots in the electronic system;
identifying one or more sections of a cooling system corresponding to the one or more hot spots, wherein each of the one or more sections comprises an independently operable thermoelectric device;
determining one or more adjustments to operating parameters of the cooling system; and
applying the one or more adjustments to the operating parameters to the cooling system.

12. The method of example 11 wherein:
the one or more signals are associated with a direct measurement of the temperature in each of the plurality of locations; and
identifying the one or more hot spots in the electronic system comprises, for each individual location in the plurality of locations, comparing the temperature to a threshold temperature specific to the individual location.

13. The method of any of examples 11 and 12 wherein:
the one or more signals are associated with a workload assigned to the one or more processing devices in each of the plurality of locations; and
identifying the one or more hot spots in the electronic system comprises:
   predicting the temperature at each of the plurality of locations based on the workload assigned to the one or more processing devices; and
   for each individual location in the plurality of locations, comparing the predicted temperature to a threshold temperature specific to the individual location.

14. The method of any of examples 11-13 wherein:
identifying the one or more hot spots in the electronic system is based on a comparison of the temperature at each of the plurality of locations to threshold temperatures specific to each of the plurality of locations; and
for each individual location, the threshold temperature is based on one or more of:
   a user input associated with the threshold temperature;
   a manufacturing preset associated with the one or more processing devices in the individual location;
   a time-sensitivity of computing operations assigned to the one or more processing devices in the individual location;
   a priority of the computing operations assigned to the one or more processing devices in the individual location; and/or
   an energy-consumption preset for the cooling system.

15. The method of any of examples 11-14 wherein the one or more adjustments to the operating parameters comprise adjustments to an input electric current for the independently operable thermoelectric device in two or more of the one or more sections.

16. The method of any of examples 11-15 wherein the one or more adjustments to the operating parameters comprise adjustments to a flow rate of an internal fluid loop in one of the one or more sections.

17. The method of any of examples 11-16 wherein the one or more adjustments to the operating parameters comprise adjustments to a flow rate of an external fluid loop thermally coupled to at least one of the one or more sections.

18. A computing system, comprising:
a first processing unit;
a second processing unit operable to implement computing operations independent from the first processing unit; and
and a cooling system, comprising:
   a first thermoelectric component, wherein the first thermoelectric component is operable to create a first temperature gradient between a first cold side and a first hot side in response to a first input current, and wherein the first cold side is thermally coupled to the first processing unit;
   a second thermoelectric component, wherein the second thermoelectric component is operable to create a second temperature gradient between a second cold side and a second hot side in response to a second input current, and wherein the second cold side is thermally coupled to the second processing unit;
   a heat exchanger thermally coupled the first hot side of the first thermoelectric component and the second hot side of the second thermoelectric component;
   and an external cooling loop operably coupled to the heat exchanger, the external cooling loop operable to drive a cooling fluid through the heat exchanger and carry heat away from the heat exchanger.

19. The computing system of example 18, further comprising a controller operably coupled to the first thermoelectric component, the second thermoelectric component, and the external cooling loop to independently apply operating parameters to each of the first thermoelectric component, the second thermoelectric component, and the external cooling loop.

20. The computing system of example 19 wherein the controller is configured to adjust the operating parameters independently for each of the first thermoelectric component, the second thermoelectric component, and the external cooling loop.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology can be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications can be made without deviating from the disclosure or the technology. For example, one of ordinary skill in the art will understand that various components of the technology can be further divided into subcomponents, or that various components and functions of the technology can be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A cooling system for removing heat from an electronic device comprising two or more processing units, the cooling system comprising:
a first thermoelectric component having a first cold side and a first hot side, wherein the first cold side is thermally couplable to a first processing unit from the two or more processing units;
a second thermoelectric component having a second cold side and a second hot side, wherein the second cold side is thermally couplable to a second processing unit from the two or more processing units, and wherein the second thermoelectric component is operable independent from the first thermoelectric component;
a heat exchanger thermally coupled the first hot side of the first thermoelectric component; and
an external cooling loop, the external cooling loop comprising:
an input channel fluidly coupled to the heat exchanger to deliver a fluid at a first temperature to a channel within the heat exchanger; and
an output channel fluidly coupled to the heat exchanger to receive the fluid from the channel at a second temperature higher than the first temperature.

2. The cooling system of claim 1, wherein the heat exchanger is further thermally coupled to the second hot side of the second thermoelectric component.

3. The cooling system of claim 1, wherein:
the heat exchanger is a first heat exchanger with a first cavity, the input channel is a first input channel, and the output channel is a first output channel;
the cooling system further comprises a second heat exchanger thermally coupled to the second hot side of the second thermoelectric component; and
the external cooling loop further comprises:
a second input channel fluidly coupled to the second heat exchanger to deliver a second fluid at the first temperature to a second channel within the second heat exchanger; and
a second output channel fluidly coupled to the second heat exchanger to receive the fluid from the channel at a third temperature higher than the first temperature.

4. The cooling system of claim 1 wherein the heat exchanger is a hot-side heat exchanger, wherein the input channel is an external input channel, wherein the output channel is an external output channel, and wherein the cooling system further comprises:
a cold-side heat exchanger thermally coupled to the first cold side of the first thermoelectric component; and
an internal cooling loop thermally couplable between the cold-side heat exchanger and the first processing unit, the internal cooling loop comprising:
an internal heat exchanger positionable in thermal contact with the first processing unit;
an internal input channel, the internal input channel fluidly coupled between the cold-side heat exchanger and the internal heat exchanger to transfer a cooling fluid from the cold-side heat exchanger to the internal heat exchanger; and
an internal output channel, the internal output channel fluidly coupled between the internal heat exchanger and the cold-side heat exchanger to transfer the cooling fluid from the internal heat exchanger to the cold-side heat exchanger.

5. The cooling system of claim 4 wherein the internal cooling loop further comprises a pump fluidly coupled to the internal input channel and/or the internal output channel to control a flow rate of the fluid.

6. The cooling system of claim 1 wherein the first thermoelectric component is in thermal contact with a surface of the electronic device.

7. The cooling system of claim 1 wherein:
the heat exchanger includes a valve component fluidly coupled to the input channel; and
the valve component is operable between a first position and a second position, wherein:
in the first position, the valve component allows the fluid to flow through a portion of the heat exchanger corresponding to the first thermoelectric component; and
in the second position, the valve component prevents the fluid from flowing through the portion of the heat exchanger corresponding to the first thermoelectric component.

8. The cooling system of claim 1, further comprising a controller operably coupled to the first thermoelectric component and the second thermoelectric component, wherein the controller is configured to independently drive the first thermoelectric component and the second thermoelectric component in response to temperatures in the first processing unit and the second processing unit.

9. The cooling system of claim 1, further comprising a controller comprising a processor and a memory storing instructions that, when executed by the processor, cause the controller to:
receive signals indicative of a first temperature in the first processing unit and a second temperature the second processing unit;
determine, based on the first temperature and the second temperature, one or more adjustments to operating parameters of the first thermoelectric component and the second thermoelectric component, wherein the one or more adjustments alter a cooling power delivered by the first thermoelectric component and the second thermoelectric component; and
apply the one or more adjustments to the operating parameters to the first thermoelectric component and the second thermoelectric component.

10. The cooling system of claim 9 wherein the one or more adjustments are based on:
a first comparison between the first temperature and a first threshold temperature for the first processing unit; and
a second comparison between the first temperature and a second threshold temperature for the second processing unit.

11. A method for operating a cooling system for removing heat from an electronic system, the method comprising:
receiving one or more signals associated with a temperature at each of a plurality of locations in the electronic system, each of the plurality of locations comprising one or more processing devices;
identifying one or more hot spots in the electronic system;
identifying one or more sections of a cooling system corresponding to the one or more hot spots, wherein each of the one or more sections comprises an independently operable thermoelectric device;
determining one or more adjustments to operating parameters of the cooling system; and
applying the one or more adjustments to the operating parameters to the cooling system.

12. The method of claim 11 wherein:
the one or more signals are associated with a direct measurement of the temperature in each of the plurality of locations; and
identifying the one or more hot spots in the electronic system comprises, for each individual location in the plurality of locations, comparing the temperature to a threshold temperature specific to the individual location.

13. The method of claim 11 wherein:
the one or more signals are associated with a workload assigned to the one or more processing devices in each of the plurality of locations; and
identifying the one or more hot spots in the electronic system comprises:
predicting the temperature at each of the plurality of locations based on the workload assigned to the one or more processing devices; and
for each individual location in the plurality of locations, comparing the predicted temperature to a threshold temperature specific to the individual location.

14. The method of claim 11 wherein:
identifying the one or more hot spots in the electronic system is based on a comparison of the temperature at each of the plurality of locations to threshold temperatures specific to each of the plurality of locations; and
for each individual location, the threshold temperature is based on one or more of:
a user input associated with the threshold temperature;
a manufacturing preset associated with the one or more processing devices in the individual location;
a time-sensitivity of computing operations assigned to the one or more processing devices in the individual location;
a priority of the computing operations assigned to the one or more processing devices in the individual location; and/or
an energy-consumption preset for the cooling system.

15. The method of claim 11 wherein the one or more adjustments to the operating parameters comprise adjustments to an input electric current for the independently operable thermoelectric device in two or more of the one or more sections.

16. The method of claim 11 wherein the one or more adjustments to the operating parameters comprise adjustments to a flow rate of an internal fluid loop in one of the one or more sections.

17. The method of claim 11 wherein the one or more adjustments to the operating parameters comprise adjustments to a flow rate of an external fluid loop thermally coupled to at least one of the one or more sections.

18. A computing system, comprising:
a first processing unit;
a second processing unit operable to implement computing operations independent from the first processing unit; and
and a cooling system, comprising:
a first thermoelectric component, wherein the first thermoelectric component is operable to create a first temperature gradient between a first cold side and a first hot side in response to a first input current, and wherein the first cold side is thermally coupled to the first processing unit;
a second thermoelectric component, wherein the second thermoelectric component is operable to create a second temperature gradient between a second cold side and a second hot side in response to a second input current, and wherein the second cold side is thermally coupled to the second processing unit;
a heat exchanger thermally coupled the first hot side of the first thermoelectric component and the second hot side of the second thermoelectric component; and
an external cooling loop operably coupled to the heat exchanger, the external cooling loop operable to drive a cooling fluid through the heat exchanger and carry heat away from the heat exchanger.

19. The computing system of claim 18, further comprising a controller operably coupled to the first thermoelectric component, the second thermoelectric component, and the external cooling loop to independently apply operating parameters to each of the first thermoelectric component, the second thermoelectric component, and the external cooling loop.

20. The computing system of claim 19 wherein the controller is configured to independently adjust the operating parameters for each of the first thermoelectric component, the second thermoelectric component, and the external cooling loop.
